(19) United States
(12) Patent Application Publication
(10) Pub. No.: US 2008/0073733 A1
(43) Pub. Date: Mar. 27, 2008

(54) Semiconductor device and method for manufacturing the same

(76) Inventors: Chiaki Kudo, Hyogo (JP); Yoshihiro Sato, Hyogo (JP)

Correspondence Address: MCDERMOTT WILL & EMERY LLP, 600 13TH STREET, NW, WASHINGTON, DC, 20005-3096, US

(21) Appl. No.: 11/819,192

(22) Filed: Jun. 26, 2007

(30) Foreign Application Priority Data
Sep. 21, 2006 (JP) 2006-256182

(51) Int. Cl. H01L 21/3205; H01L 21/336; H01L 29/76

(52) U.S. Cl. 257/412; 438/303; 257/E29.226; 257/E21.296; 257/E21.409

(57) ABSTRACT

A semiconductor device includes a MIS transistor having a gate electrode which is fully silicided with metal. The edge parts of the gate electrode are lower in height than the other part thereof. Sidewall spacers are formed to cover the side and top surfaces of the edge parts of the gate electrode.

### BACKGROUND OF THE INVENTION

1. Field of the Invention

The present invention relates to a semiconductor device and a method for manufacturing the same. In particular, it relates to a semiconductor device including field effect transistors having fully silicided (FUSI) structure and a method for manufacturing the same.

2. Description of Related Art

As semiconductor elements are integrated to a higher degree, gate electrodes for forming MIS (metal-insulator-semiconductor) field-effect transistors (FETs) are scaled down and the electrical thickness of a gate insulating film is reduced by using highly dielectric material for the gate insulating film. In this trend, for example, if polysilicon is used for the gate electrode, depletion occurs inevitably in the polysilicon gate electrode even if impurities are implanted therein. The depletion increases the electrical thickness of the gate insulating film. This has been an obstacle to improvement in performance of the FET.

In recent years, various gate electrode structures have been proposed for the purpose of preventing the depletion of the gate electrode. For example, a fully silicided (FUSI) gate electrode obtained by reacting silicon used for the gate electrode with metal for full silicidation of the silicon has been reported as an effective means of suppressing the depletion.

Japanese Unexamined Patent Publication No. 2000-252462 (Patent Literature 1) describes a method for manufacturing the FUSI gate electrodes.

FIGS. 24A to 24E are sectional views of a major part illustrating the steps of forming the FUSI electrodes in the conventional method for manufacturing MISFETs according to Patent Literature 1.

As shown in FIG. 24A, an isolation film 2 is formed in an upper portion of a semiconductor substrate 1 made of silicon and ion implantation is performed to form a well and a channel stopper (not shown). As a result, part of the semiconductor substrate 1 surrounded by the isolation film 2 is defined as an active region. Then, a gate insulating film 3 and a conductive polysilicon film 4 are formed in this order on the semiconductor substrate 1 and the polysilicon film 4 is patterned into the form of a gate electrode. Further, ion implantation is performed to form extension regions 8 in parts of the active region of the semiconductor substrate 1 on the sides of the patterned polysilicon film 4. Then, sidewall spacers 5 are formed on the side surfaces of the patterned polysilicon film 4. Using the sidewall spacers 5 and the patterned polysilicon film 4 as a mask, ions are implanted into the active region of the semiconductor substrate 1 to form source/drain regions 6.

Subsequently, an interlayer insulating film 7 is deposited on the entire surface of the semiconductor substrate 1 as shown in FIG. 24B and planarized by CMP (chemical mechanical polishing) to expose the top surface of the patterned polysilicon film 4 as shown in FIG. 24C.

Then, a Co film is deposited as a metallic film 10 on the patterned polysilicon film 4 and the interlayer insulating film 7 as shown in FIG. 24D and RTA (rapid thermal annealing) is performed to cause reaction between the polysilicon film 4 and the metallic film 10. As a result, the patterned polysilicon film 4 is fully substituted into silicide material 11 made of CoSi₂ as shown in FIG. 24E, thereby forming a gate electrode of FUSI structure. Thereafter, unreacted part of the metallic film 10 is removed by selective etching.

### SUMMARY OF THE INVENTION

If the gate electrode of the MISFET is converted to the FUSI gate electrode by the above-described conventional art, the silicon film for forming the gate electrode may not be silicided uniformly and the threshold voltage may vary. This phenomenon significantly occurs in the full silicidation of a gate electrode having a relatively large gate length.

Further, if the conventional full silicidation method is used to form a resistance element or an upper electrode of a capacitative element, silicon material may not be silicided uniformly. As a result, the resistance value of the resistance element or the capacitance value of the capacitative element may vary.

In light of the above-described situation, an object of the present invention is to provide a semiconductor device including elements having FUSI structure of uniform composition and a method for manufacturing the same, particularly to provide a semiconductor device including a MISFET having a gate electrode of FUSI structure of uniform composition irrespective of the gate length and a method for manufacturing the same.

The inventors' close study on the cause of nonuniform silicidation in the conventional FUSI gates has produced findings as shown in FIGS. 25A and 25B. In FIGS. 25A and 25B, the same components as those shown in FIGS. 24A to 24E are indicated by the same reference numerals to omit overlapping explanation.

As shown in FIG. 25A, a first silicon film 4A made of polysilicon and a second silicon film 4B made of polysilicon are formed on an active region of a semiconductor substrate 1. The first and second silicon films 4A and 4B have been patterned in the form of a gate electrode, respectively, while the second silicon film 4B has a gate length larger than that of the first silicon film 4A. A metallic film 10 is formed on the silicon films 4A and 4B. In this case, metal atoms are diffused into the silicon films 4A and 4B not only from parts of the metallic film 10 deposited immediately on the silicon films 4A and 4B, but also from parts of the metallic film 10 deposited on and near sidewall spacers 5 formed on the side surfaces of the silicon films 4A and 4B. That is, an excess amount of the metal atoms is supplied to the silicon films 4A and 4B from parts of the metallic film 10 on both sides of the silicon films 4A and 4B in the gate length direction. As a result, parts of the silicon films 4A and 4B adjacent to the sidewall spacers 5 are silicided too much.

As a result, as shown in FIG. 25B, if the first silicon film 4A whose gate length is relatively small is fully silicided to obtain a first gate electrode 14 of desired composition, the second silicon film 4B whose gate length is relatively large cannot be fully silicided. Therefore, the second silicon film 4B made of polysilicon may partially remain below a second gate electrode 15 formed by silicidation.

Though not shown, if the second silicon film 4B having relatively large gate length is fully silicided to obtain the second gate electrode 15 of desired composition, metal is excessively supplied to the first silicon film 4A having the relatively small gate length and the resulting first gate electrode 14 becomes metal-richer than the desired composition.

In the full silicidation of the second silicon film 4B having the relatively large gate length, a middle part of the second silicon film 4B away from the sidewall spacers 5 is supplied with metal from only part of the metallic film 10 deposited immediately on the middle part, while parts of the second silicon film 4B adjacent to the sidewall spacers 5 are supplied with metal not only from the part of the metallic film 10 deposited immediately on the parts but also from parts of the metallic film 10 deposited on and near the sidewall spacers 5. The metal diffuses faster at the interface between the second silicon film 4B and the sidewall spacers 5 than in the middle of the second silicon film 4B. Therefore, the parts of the second silicon film 4B adjacent to the sidewall spacers 5 are silicided with an excess amount of metal as compared with the middle part of the second silicon film 4B away from the sidewall spacers 5. As a result, in the obtained second gate electrode 15, the parts adjacent to the sidewall spacers 5 become metal-richer than the middle part away from the sidewall spacers 5, i.e., the composition of the second gate electrode 15 varies. Thus, in the FET having the relatively large gate length, the composition of the gate electrode varies between the parts adjacent to the sidewall spacers 5 and the middle part. This is a cause of variations in threshold voltage of the FET.

Based on the above finding, the inventors of the present invention have conceived to cover the top surfaces of the edge parts of the gate electrode with the sidewall spacers formed on the side surfaces of the gate electrode for the purpose of preventing variations in silicidation composition of a FUSI structure.

More specifically, a semiconductor device according to the present invention includes a first MIS transistor having a first gate electrode which is fully silicided with metal, wherein edge parts of the first gate electrode are lower in height than the other part thereof and first sidewall spacers are formed to cover side and top surfaces of the edge parts of the first gate electrode.

In other words, the semiconductor device according to the present invention includes a first MIS transistor having a first gate electrode which is fully silicided with metal. The first MIS transistor includes: a first gate insulating film formed on a semiconductor substrate; the first gate electrode formed on the first gate insulating film; and first sidewall spacers formed on the side surfaces of the first gate electrode. The first gate electrode has a first part and a second part which is formed on the first part and has a width in the gate length direction smaller than that of the first part. The second part of the first gate electrode is sandwiched between the first sidewall spacers formed on the side surfaces thereof.

As to the semiconductor device of the present invention, the first sidewall spacers are formed to cover the top surfaces of the edge parts of the first gate electrode which is fully silicided with metal. That is, in the manufacture of the semiconductor device of the present invention, a silicon film pattern which will be the first gate electrode is fully silicided with a metallic film while the top surfaces of the edge parts of the silicon film pattern are covered with the first sidewall spacers, i.e., the top surfaces of the edge parts of the silicon film pattern are not in direct contact with the metallic film. Therefore, to the edge parts of the silicon film pattern, i.e., parts of the silicon film pattern adjacent to the sidewall spacers, metal is not supplied from part of the metallic film deposited immediately thereon, but only from part of the metallic film deposited on and near the sidewall spacers. As a result, the metal supplied from the part of the metallic film deposited on and near the sidewall spacers to the silicon film pattern, which has been excess amount according to the conventional art, is consumed in the silicidation of the edge parts of the silicon film pattern covered with the sidewall spacers. Thus, the amount of metal supplied to parts of the silicon film pattern adjacent to the sidewall spacers becomes equal to the amount of metal supplied to a middle part of the silicon film pattern away from the sidewall spacers from the part of the metallic film deposited immediately on the middle part. Since the silicidation is performed while the top surfaces of the edge parts of the silicon film pattern to be the first gate electrode are covered with the sidewall spacers, the interface between the silicon film pattern and the sidewall spacers is broadened and the distance traveled by the diffusing metal along the interface is increased. This makes it possible to suppress accelerated silicidation of the parts of the silicon film pattern adjacent to the sidewall spacers, i.e., the gate edges. As substantially the same amount of metal is supplied to every part of the silicon film pattern during the silicidation, silicide of almost the same composition is obtained in both of the parts adjacent to the sidewall spacers and the middle part away from the sidewall spacers. As a result, the first gate electrode is provided with a FUSI structure of substantially uniform composition in every part. This suppresses the variations in threshold voltage.

As to the semiconductor device of the present invention, the silicidation of the silicon film pattern which will be the first gate electrode is performed while the top surface of the silicon film pattern is partially covered with the sidewall spacers. Therefore, stress caused by expansion of the silicon film pattern during the silicidation is placed on the substrate. This makes it possible to improve the drive performance of the first MIS transistor.

If the FUSI structure of the gate electrode of the semiconductor device of the present invention is applied to a resistance element or an upper electrode of a capacitative element, the resistance element or the upper electrode of the capacitative element is also achieved with the FUSI structure of uniform composition.

As to the semiconductor device of the present invention, the first sidewall spacers may have a laminated structure of insulating films.

As to the semiconductor device of the present invention, part of the first gate electrode other than the edge parts thereof may be substantially flush with or higher or lower in height than the top end of the first sidewall spacers. The first gate electrode may be convex-shaped when viewed in section (cross section vertical to the principal surface of the substrate and parallel to the gate length direction). If the other part of the first gate electrode is higher in height than the top end of the first sidewall spacers, a portion of the other part protruding from the top end of the first sidewall spacers may be formed wider than a portion of the other part sandwiched between the first sidewall spacers.

As to the semiconductor device of the present invention, the first sidewall spacers may include first internal sidewall spacers covering the top surfaces of the edge parts of the first gate electrode and side surfaces of the other part of the first gate electrode and first external sidewall spacers covering the side surfaces of the edge parts of the first gate electrode and the first internal sidewall spacers. In other words, the first sidewall spacers may include first internal sidewall spacers covering the side surfaces of the second part of the first gate electrode and first external sidewall spacers covering the side surfaces of the first part of the first gate electrode and side surfaces of the second part of the first gate electrode with the first internal sidewall spacers interposed therebetween. In this case, the first external sidewall spacers may have a laminated structure of insulating films.

The semiconductor device of the present invention further includes a second MIS transistor having a second gate electrode which is fully silicided with metal and has a gate length larger than that of the first gate electrode, wherein edge parts of the second gate electrode are lower in height than the other part thereof and second sidewall spacers are formed to cover side and top surfaces of the edge parts of the second gate electrode. In other words, the semiconductor device of the present invention further includes a second MIS transistor having a second gate electrode which is fully silicided with metal and has a gate length larger than that of the first gate electrode. The second MIS transistor includes: a second gate insulating film formed on the semiconductor substrate; the second gate electrode formed on the second insulating film; and second sidewall spacers formed on the side surfaces of the second gate electrode. The second gate electrode has a third part and a fourth part which is formed on the third part and has a width in the gate length direction smaller than that of the third part. That is, in the manufacture of the semiconductor device of the present invention, the silicon film patterns for forming the first and second gate electrodes having different gate lengths may be fully silicided with the metallic film to cause full silicidation while the top surfaces of the edge parts of the silicon film patterns are covered with the sidewall spacers, i.e., the top surfaces of the edge parts of the silicon film patterns are not in direct contact with the metallic film. As a result, during the silicidation, in each of the silicon film patterns having different gate lengths, the amount of metal supplied to parts adjacent to the sidewall spacers becomes equal to the amount of metal supplied to a middle part away from the sidewall spacers. Further, the interfaces between the silicon film patterns and the sidewall spacers are broadened, respectively, and the distance traveled by the diffusing metal along each of the interfaces is increased to suppress accelerated silicidation of the gate edges. Therefore, in the silicidation of each of the silicide film patterns, silicide of almost the same composition is obtained in both of the parts adjacent to the sidewall spacers and the middle part away from the sidewall spacers. As a result, each of the gate electrodes is provided with a FUSI structure of uniform composition in every part irrespective of the gate length. This suppresses the variations in threshold voltage. Further, in the silicidation of the silicon film pattern to be the second gate electrode, the top surface of the silicon film pattern is partially covered with the sidewall spacers. Therefore, stress caused by expansion of the silicon film pattern during the silicidation is placed on the substrate. This makes it possible to improve the drive performance of the second MIS transistor.

If the semiconductor device of the present invention includes the second MIS transistor having the second gate electrode, the first MIS transistor including the first gate electrode and the second MIS transistor including the second gate electrode may have the same conductivity type or different conductive types. The second sidewall spacers may have a laminated structure of insulating films. Part of the second gate electrode other than the edge parts thereof may be substantially flush with or higher or lower in height than the top end of the second sidewall spacers. The second gate electrode may be convex-shaped when viewed in section (cross section vertical to the principal surface of the substrate and parallel to the gate length direction). If the other part of the second gate electrode is higher in height than the top end of the second sidewall spacers, a portion of the other part protruding from the top end of the second sidewall spacers may be formed wider than a portion of the other part sandwiched between the second sidewall spacers.

If the semiconductor device of the present invention includes the second MIS transistor having the second gate electrode, the second sidewall spacers may include second internal sidewall spacers covering the top surfaces of the edge parts of the second gate electrode and side surfaces of the other part of the second gate electrode and second external sidewall spacers covering the side surfaces of the edge parts of the second gate electrode and the second internal sidewall spacers. That is, the second sidewall spacers may include second internal sidewall spacers covering side surfaces of the fourth part of the second gate electrode and second external sidewall spacers covering side surfaces of the third part of the second gate electrode and the side surfaces of the fourth part of the second gate electrode with the second internal sidewall spacers interposed therebetween. In this case, the second external sidewall spacers may have a laminated structure of insulating films.

A method for manufacturing a semiconductor device according to the present invention is a method for manufacturing a semiconductor device including a first MIS transistor having a first gate electrode which is fully silicided with metal. The method includes the steps of: (a) forming first sidewall spacers covering side and top surfaces of edge parts of a first silicon film pattern to be the first gate electrode; (b) forming a metallic film on the first silicon film pattern after the step (a); and (c) reacting the first silicon film pattern with the metallic film to cause full silicidation of the first silicon film pattern to form the first gate electrode after the step (b).

According to the method of the present invention, a silicon film pattern which will be the first gate electrode is fully silicided with a metallic film while the top surfaces of the edge parts of the silicon film pattern are covered with the first sidewall spacers, i.e., the top surfaces of the edge parts of the silicon film pattern are not in direct contact with the metallic film. Therefore, to the edge parts of the silicon film pattern, i.e., parts of the silicon film pattern adjacent to the sidewall spacers, metal is not supplied from part of the metallic film deposited immediately thereon, but only from part of the metallic film deposited on and near the sidewall spacers. As a result, the metal supplied from the part of the metallic film deposited on and near the sidewall spacers to the silicon film pattern, which has been excess amount according to the conventional art, is consumed in the silicidation of the edge parts of the silicon film pattern covered with the sidewall spacers. Thus, the amount of metal supplied to parts of the silicon film pattern adjacent to the sidewall spacers becomes equal to the amount of metal supplied to a middle part of the silicon film pattern away from the sidewall spacers from the part of the metallic film deposited immediately on the middle part. Since the silicidation is performed while the top surfaces of the edge parts of the silicon film pattern to be the gate electrode are covered with the sidewall spacers, the interface between the silicon film pattern and the sidewall spacers is broadened and the distance traveled by the diffusing metal along the interface is increased. This makes it possible to suppress accelerated silicidation of the parts of the silicon film pattern adjacent to the sidewall spacers, i.e., the gate edges. As substantially the same amount of metal is supplied to every part of the silicon film pattern during the silicidation, silicide of almost the same composition is obtained in both of the parts adjacent to the sidewall spacers and the middle part away from the sidewall spacers. As a result, the first gate electrode is provided with a FUSI structure of substantially uniform composition in every part. This suppresses the variations in threshold voltage.

According to the method of the present invention, the silicidation of the silicon film pattern which will be the first gate electrode is performed while the top surface of the silicon film pattern is partially covered with the sidewall spacers. Therefore, stress caused by expansion of the silicon film pattern during the silicidation is placed on the substrate. This makes it possible to improve the drive performance of the first MIS transistor.

If the method for manufacturing the gate electrode having the FUSI structure according to the present invention is applied to form a resistance element or an upper electrode of a capacitative element, the resistance element or the upper electrode of the capacitative element is also achieved with the FUSI structure of uniform composition.

According to the method of the present invention, the silicon film which is silicided to be the gate electrode may be implanted with impurities.

According to the method of the present invention, the semiconductor device may further include a second MIS transistor having a second gate electrode which is fully silicided with metal and has a gate length larger than that of the first gate electrode. Further, the step (a) may include the step of forming second sidewall spacers covering side and top surfaces of edge parts of a second silicon film pattern to be the second gate electrode, the step (b) may include the step of forming the metallic film on the second silicon film pattern and the step (c) may include the step of reacting the second silicon film pattern with the metallic film to cause full silicidation of the second silicon film pattern to form the second gate electrode. That is, the silicon film patterns for forming the first and second gate electrodes having different gate lengths may be fully silicided with the metallic film to cause full silicidation while the top surfaces of the edge parts of the silicon film patterns are covered with the sidewall spacers, i.e., the top surfaces of the edge parts of the silicon film patterns are not in direct contact with the metallic film. As a result, during the silicidation, in each of the silicon film patterns having different gate lengths, the amount of metal supplied to parts adjacent to the sidewall spacers becomes equal to the amount of metal supplied to a middle part away from the sidewall spacers. Further, the interfaces between the silicon film patterns and the sidewall spacers are broadened, respectively, and the distance traveled by the diffusing metal along each of the interfaces is increased to suppress accelerated silicidation of the gate edges. Therefore, in the silicidation of each of the silicide film patterns, silicide of almost the same composition is obtained in both of the parts adjacent to the sidewall spacers and the middle part away from the sidewall spacers. As a result, each of the gate electrodes is provided with a FUSI structure of uniform composition in every part irrespective of the gate length. This suppresses the variations in threshold voltage. Further, in the silicidation of the silicon film pattern to be the second gate electrode, the top surface of the silicon film pattern is partially covered with the sidewall spacers. Therefore, stress caused by expansion of the silicon film pattern during the silicidation is placed on the substrate. This makes it possible to improve the drive performance of the second MIS transistor.

If the second MIS transistor having the second gate electrode is formed by the method according to the present embodiment, the first MIS transistor including the first gate electrode and the second MIS transistor including the second gate electrode may have the same conductivity type or different conductivity types.

As to the method of the present embodiment, the step (a) may include the step of forming a silicon film and a protective film sequentially on a substrate, shaping the protective film and the silicon film into the form of the first gate electrode to obtain a first protective film pattern and a first silicon film pattern, reducing the width of the first protective film pattern from both edges thereof to expose top surfaces of edge parts of the first silicon film pattern and forming the first sidewall spacers to cover the side and top surfaces of the edge parts and the step of removing the first protective film pattern may be performed between the steps (a) and (b). According to the method, the first sidewall spacers covering the side and top surfaces of the edge parts of the first silicon film pattern are obtained by removing the first protective film pattern. Therefore, large stress caused by expansion of the first silicon film pattern during the full silicidation thereof is placed effectively on the substrate (channel region).

As to the method of the present invention, the first sidewall spacers may include internal sidewall spacers covering the top surfaces of the edge parts of the first silicon film pattern and external sidewall spacers covering the side surfaces of the edge parts of the first silicon film pattern and the internal sidewall spacers, the step (a) may include the step of forming a silicon film and a protective film sequentially on a substrate, shaping the protective film into a first protective film pattern having a width smaller than the width of the first gate electrode by a predetermined amount reduced from both sides of the first gate electrode, forming the internal sidewall spacers to cover top surfaces of parts of the silicon film to be edge parts of the first gate electrode and the side surfaces of the first protective film pattern, shaping the silicon film into the form of the first gate electrode using the first protective film pattern and the internal sidewall spacers as a mask to obtain a first silicon film pattern and forming the external sidewall spacers to cover side surfaces of edge parts of the first silicon film pattern and the internal sidewall spacers and the step of removing the first protective film pattern may be performed between the steps (a) and (b). According to the method, the widths of the top surfaces of the edge parts of the first silicon film pattern to be covered with the internal sidewall spacers are easily controlled by controlling the thickness of the internal sidewall spacers.

As to the method of the present invention, the step (a) may include the step of forming a silicon film and a protective film sequentially on a substrate, shaping the protective film into a first protective film pattern having a width smaller than the width of the first gate electrode by a predetermined amount reduced from both sides of the first gate electrode, forming dummy sidewall spacers to cover top surfaces of parts of the silicon film to be edge parts of the first gate electrode and the side surfaces of the first protective film pattern, shaping the silicon film into the form of the first gate electrode using the first protective film pattern and the dummy sidewall spacers as a mask to obtain a first silicon film pattern, removing the dummy sidewall spacers to expose the top surfaces of the edge parts of the first silicon film pattern and forming the first sidewall spacers to cover the side and top surfaces of the edge parts and the step of removing the first protective film pattern may be performed between the steps (a) and (b). According to the method, the widths of the top surfaces of the edge parts of the first silicon film pattern to be covered with the first sidewall spacers are easily controlled by controlling the thickness of the dummy sidewall spacers. Further, as the side and top surfaces of the edge parts of the first silicon film pattern are covered with the first sidewall spacers, large stress caused by the full silicidation of the first silicon film pattern is effectively applied to the substrate (channel region).

Thus, as described above, as to the semiconductor device and the method for manufacturing the same according to the present invention, a gate electrode having a FUSI structure of uniform composition is obtained irrespective of the gate length thereof. This makes it possible to suppress variations in threshold voltage.

Further, as to the semiconductor device and the method for manufacturing the same according to the present invention, the silicon film for forming the gate electrode is fully silicided while the top surface thereof is partially covered with the sidewall spacers. Therefore, stress caused by expansion of the silicon film pattern during the silicidation is placed on the substrate. This makes it possible to improve the drive performance of the transistor.

That is, the present invention relates to a semiconductor device and a method for manufacturing the same. In particular, if the present invention is applied to a semiconductor device including a field-effect transistor having a FUSI gate electrode and a method for manufacturing the same, the FUSI structure is effectively obtained with uniform composition.

### BRIEF DESCRIPTION OF THE DRAWINGS

FIG. 1 is a schematic sectional view illustrating a semiconductor device according to a first embodiment of the present invention.

FIG. 2 is a sectional view illustrating a step of a method for manufacturing the semiconductor device according to the first embodiment of the present invention.

FIG. 3 is a sectional view illustrating a step of the method for manufacturing the semiconductor device according to the first embodiment of the present invention.

FIG. 4 is a sectional view illustrating a step of the method for manufacturing the semiconductor device according to the first embodiment of the present invention.

FIG. 5 is a sectional view illustrating a step of the method for manufacturing the semiconductor device according to the first embodiment of the present invention.

FIG. 6 is a sectional view illustrating a step of the method for manufacturing the semiconductor device according to the first embodiment of the present invention.

FIG. 7 is a sectional view illustrating a step of the method for manufacturing the semiconductor device according to the first embodiment of the present invention.

FIG. 8 is a schematic sectional view illustrating a semiconductor device according to a second embodiment of the present invention.

FIG. 9 is a sectional view illustrating a step of a method for manufacturing the semiconductor device according to the second embodiment of the present invention.

FIG. 10 is a sectional view illustrating a step of the method for manufacturing the semiconductor device according to the second embodiment of the present invention.

FIG. 11 is a sectional view illustrating a step of the method for manufacturing the semiconductor device according to the second embodiment of the present invention.

FIG. 12 is a sectional view illustrating a step of the method for manufacturing the semiconductor device according to the second embodiment of the present invention.

FIG. 13 is a sectional view illustrating a step of the method for manufacturing the semiconductor device according to the second embodiment of the present invention.

FIG. 14 is a sectional view illustrating a step of the method for manufacturing the semiconductor device according to the second embodiment of the present invention.

FIG. 15 is a sectional view illustrating a step of the method for manufacturing the semiconductor device according to the second embodiment of the present invention,

FIG. 16 is a sectional view illustrating a step of the method for manufacturing the semiconductor device according to the second embodiment of the present invention.

FIG. 17 is a schematic sectional view illustrating a semiconductor device according to a third embodiment of the present invention.

FIG. 18 is a sectional view illustrating a step of a method for manufacturing the semiconductor device according to the third embodiment of the present invention.

FIG. 19 is a sectional view illustrating a step of the method for manufacturing the semiconductor device according to the third embodiment of the present invention.

FIG. 20 is a sectional view illustrating a step of the method for manufacturing the semiconductor device according to the third embodiment of the present invention.

FIG. 21 is a sectional view illustrating a step of the method for manufacturing the semiconductor device according to the third embodiment of the present invention.

FIG. 22 is a sectional view illustrating a step of the method for manufacturing the semiconductor device according to the third embodiment of the present invention.

FIG. 23 is a sectional view illustrating a step of the method for manufacturing the semiconductor device according to the third embodiment of the present invention.

FIGS. 24A to 24E are sectional views illustrating the steps of forming a FUSI electrode in a conventional method for manufacturing a MISFET.

FIGS. 25A and 25B are sectional views for explaining a cause of variations in silicidation in a conventional FUSI structure.

### DETAILED DESCRIPTION OF THE INVENTION

### First Embodiment

Hereinafter, explanation of a semiconductor device and a method for manufacturing the same according to a first embodiment of the present invention is provided with reference to the drawings. In the present embodiment, n-FETs are formed as a first FET Ill and a second FET 112.

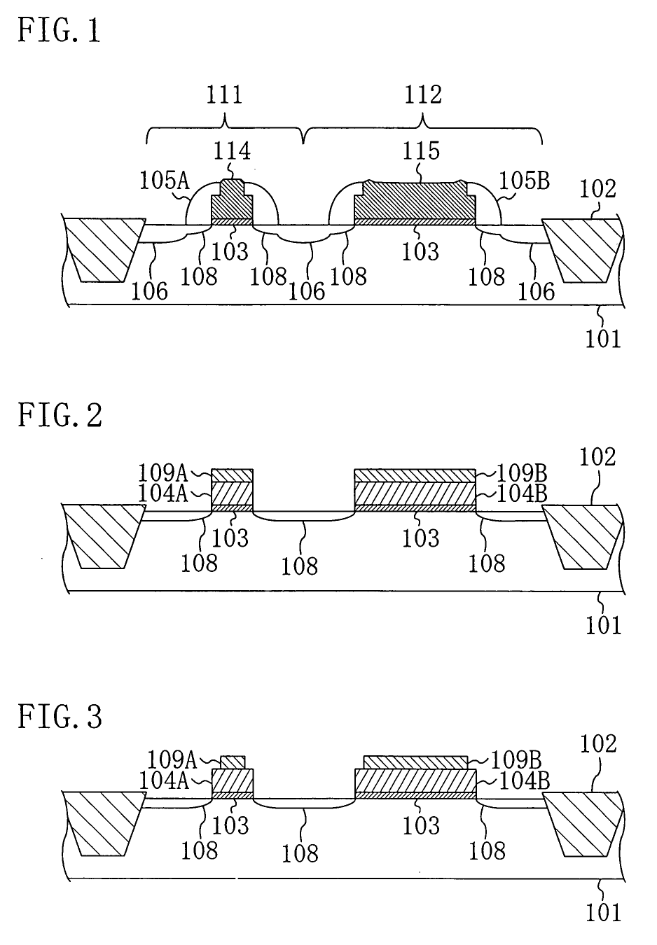

FIG. 1 shows the sectional structure of the semiconductor device according to the present embodiment. As shown in FIG. 1, for example, an isolation region 102 is formed by a shallow trench isolation (STI) technique in the principal surface of a semiconductor substrate 101 made of silicon (Si) to define an active region and a region for forming a resistance element. In the present embodiment, a first FET 111 and a second FET 112 having different gate lengths are formed on the active region. More specifically, the first FET 111 includes a gate insulating film 103 formed on the active region of the semiconductor substrate 101, a first gate electrode 114 formed on the gate insulating film 103 and made of fully silicided (FUSI) metal silicide, first sidewall spacers 105A formed on the side surfaces of the first gate electrode 114 and made of silicon nitride (Si₃N₄), for example, n-type extension regions 108 formed in parts of the active region of the semiconductor substrate 101 on the sides of the first gate electrode 114 and n-type source/drain regions 106 formed in parts of the active region of the semiconductor substrate 101 on the sides of the first sidewall spacers 105A opposite to the first gate electrode 114. The n-type extension regions 108 and the source/drain regions 106 are formed by ion implantation technique. The second FET 112 includes the gate insulating film 103 formed on the active region of the semiconductor substrate 101, a second gate electrode 115 formed on the gate insulating film 103 and made of FUSI metal silicide, second sidewall spacers 105B formed on the side surfaces of the second gate electrode 115 and made of Si₃N₄, for example, n-type extension regions 108 formed in parts of the active region of the semiconductor substrate 101 on the sides of the second gate electrode 115 and n-type source/drain regions 106 formed in parts of the active region of the semiconductor substrate 101 on the sides of the second sidewall spacers 105B opposite to the second gate electrode 115. The n-type extension regions 108 and the source/drain regions 106 are formed by ion implantation technique. The gate length of the second gate electrode 115 is larger than that of the first gate electrode 114.

As a feature of the present embodiment, the edge parts of the first gate electrode 114 are lower in height than the other part thereof and the first sidewall spacers 105A are formed to cover the side and top surfaces of the edge parts. Likewise, the edge parts of the second gate electrode 115 are lower in height than the other part thereof and the second sidewall spacers 105B are formed to cover the side and top surfaces of the edge parts. As shown in FIG. 1, the first and second gate electrodes 114 and 115 are substantially convex-shaped when viewed in section, respectively.

According to the above-described structure of the present embodiment, the FUSI gate electrodes 114 and 115 having the same structure are provided with the same and uniform silicide composition in a self alignment manner irrespective of the sizes of the gate electrodes 114 and 115 (e.g., gate lengths) as described later. Therefore, in the gate electrodes 114 and 115 of the FETs 111 and 112, variations in silicide composition due to the difference in size between the gate electrodes 114 and 115 are prevented, and so are variations in threshold value.

According to the structure of the present embodiment, in the silicidation of the silicon film for forming the gate electrodes 114 and 115, the top surface of the silicon film is partially covered with the sidewall spacers 105A and 105B. Therefore, stress caused by expansion of the silicon film during the silicidation is placed on the semiconductor substrate 101. This makes it possible to improve the drive performance of the FETs 111 and 112.

In FIG. 1, two FETs 111 and 112 are shown for convenience's sake. However, in the present embodiment, a larger number of elements may be formed on the semiconductor substrate 101. Although the first and second FETs 111 and 112 of the present embodiment are formed on the same active region surrounded by the isolation region 102, they may be formed on different active regions separated by the isolation region 102. Further, the first and second FETs 111 and 112 may be either n-FETs or p-FETs or they may be different FETs.

In the semiconductor device of the present embodiment, part of the first gate electrode 114 other than the edge parts thereof may be substantially flush with or higher or lower in height than the top end of the first sidewall spacers 105A. If the other part of the first gate electrode 114 than the edge parts is higher in height than the top end of the first sidewall spacers 105A, a portion of the other part protruding from the top end of the first sidewall spacers 105A may be formed wider than a portion of the other part sandwiched between the first sidewall spacers 105A. Likewise, part of the second gate electrode 115 other than the edge parts thereof may be substantially flush with or higher or lower in height than the top end of the second sidewall spacers 105B. If the other part of the second gate electrode 115 than the edge parts is higher in height than the top end of the second sidewall spacers 105B, a portion of the other part protruding from the top end of the second sidewall spacers 105B may be formed wider than a portion of the other part sandwiched between the second sidewall spacers 105B.

If the FUSI structure of the gate electrodes 114 and 115 of the semiconductor device of the present embodiment is applied to a resistance element, an upper electrode of a capacitative element, a fuse element or the like, the resistance element, the upper electrode of the capacitative element, the fuse element or the like is also achieved with the FUSI structure of uniform composition.

Now, a method for manufacturing the semiconductor device of the present embodiment shown in FIG. 1 is explained with reference to the drawings. FIGS. 2 to 7 are sectional views sequentially illustrating the steps of the method for manufacturing the semiconductor device of the present embodiment. In FIGS. 2 to 7, the same components as those of the semiconductor device shown in FIG. 1 are indicated by the same reference numerals to omit overlapping explanation.

First, as shown in FIG. 2, for example, an isolation region 102 is formed by a STI technique in an upper portion of a semiconductor substrate 101 made of silicon and ion implantation is performed to form a well and a channel stopper (not shown). As a result, part of the semiconductor substrate 101 surrounded by the isolation region 102 is defined as an active region. A gate insulating film 103 made of hafnium oxide (HfO₂) is deposited on the active region of the principal surface of the semiconductor substrate 101 by chemical vapor deposition (CVD) up to a physical thickness of about 3 nm, for example. Then, an about 75 nm thick polysilicon film and an about 25 nm thick silicon oxide (SiO₂) film, for example, are deposited in this order by CVD on the semiconductor substrate 101 (on the active region with the gate insulating film 103 interposed therebetween) as a silicon film 104 and a protective insulating film 109, respectively. The silicon film 104 may be an amorphous silicon film or implanted with impurities. Then, a resist pattern (not shown) covering a region for forming gate electrodes is formed on the protective insulating film 109 by lithography and the protective insulating film 109 and the silicon film 104 are patterned into the form of a first gate electrode 114 and a second gate electrode 115 (in the form of lower portions of the concave-shaped first and second gate electrodes 114 and 115) by etching using the resist pattern as a mask. Thus, a first protective insulating film pattern 109A and a second protective insulating film pattern 109B are obtained and a first silicon film pattern 104A and a second silicon film pattern 104B having different gate lengths are obtained. For example, if the etching is performed by dry etching, the protective insulating film (silicon oxide film) 109 may be etched using an etching gas containing fluorocarbon as a main ingredient, and the silicon film (polysilicon film) 104 may be etched using an etching gas containing chlorine as a main ingredient. Then, using the first and second protective insulating film patterns 109A and 109B as a mask, ion implantation is performed to form n-type extension regions 108 in the active region in the surface of the semiconductor substrate 101.

Then, as shown in FIG. 3, the first and second protective insulating film patterns 109A and 109B are wet-etched using a buffered hydrofluoric acid solution, for example, to reduce their widths by about 10 nm from each of their edges, thereby exposing the top surfaces of the edge parts of the first and second silicon film patterns 104A and 104B. The silicon film patterns 104A and 104B are exposed by an almost fixed width irrespective of their gate lengths (sizes of the gate electrodes). Instead of wet etching, the protective insulating film patterns 109A and 109B may be etched by isotropic dry etching using CF₄ gas or a combination of wet etching and dry etching, for example. Alternatively, the etching of the protective insulating film patterns 109A and 109B may be performed simultaneously with the step of removing other part of the gate insulating film 103 than part thereof on the region for forming the gate electrodes after the silicon film 104 is patterned into the gate electrode form.

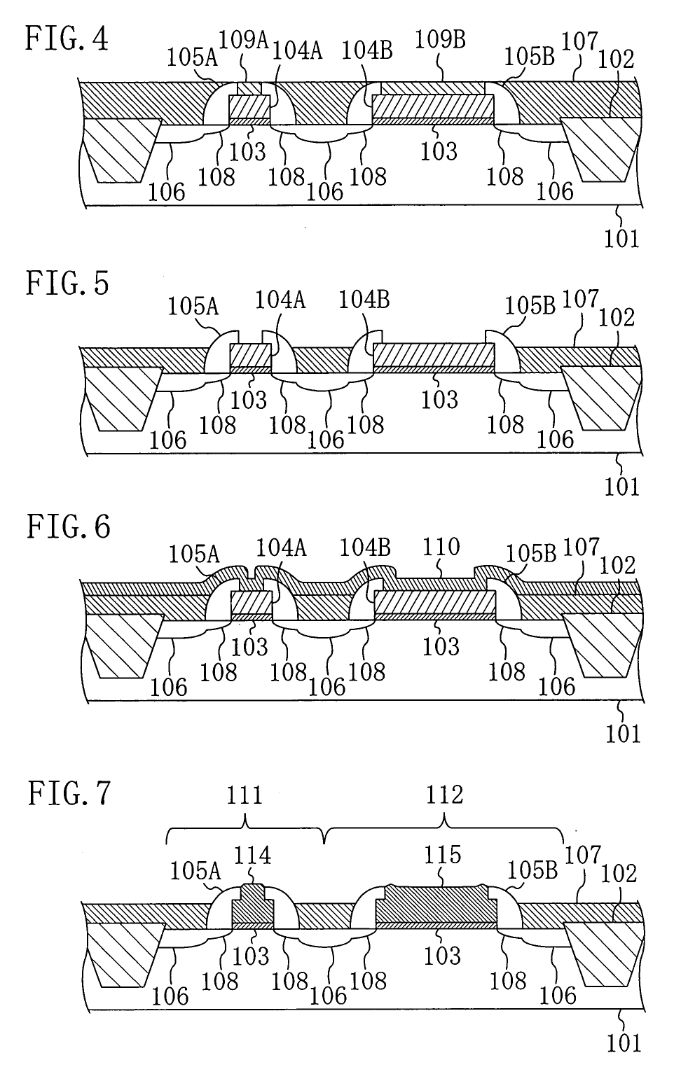

Then, a silicon nitride film is deposited on the entire surface of the semiconductor substrate 101, for example, by CVD, and etched back to form first sidewall spacers 105A on the side surfaces of the first silicon film pattern 104A and second sidewall spacers 105B on the side surfaces of the second silicon film pattern 104B as shown in FIG. 4. Since the edge parts of the first and second silicon film patterns 104A and 104B are not covered with the protective insulating film patterns 109A and 109B, the top surfaces of the edge parts of the first and second silicon film patterns 104A and 104B are also covered with the sidewall spacers 105A and 105B. Then, using the sidewall spacers 105A and 105B and the protective insulating film patterns 109A and 109B as a mask, impurities are implanted into the semiconductor substrate 101 to form n-type source/drain regions 106. Further, an interlayer insulating film 107 is deposited on the entire surface of the semiconductor substrate 101 and planarized by CMP, for example, to expose the top surfaces of the protective insulating film patterns 109A and 109B.

Though not shown, the surfaces of the n-type source/drain regions 106 formed in the step of FIG. 4 may be silicided with nickel (Ni) or the like. In this step, the silicon film patterns 104A and 104B which will be the gate electrodes 114 and 115 are not silicided because they are covered with the sidewall spacers 105A and 105B and the protective insulating film patterns 109A and 109B.

The sidewall spacers 105A and 105B of the present embodiment are formed as a single layer structure made of a silicon nitride film. However, they may be formed as a two-layer structure made of a silicon oxide film and a silicon nitride film or a three-layer structure made of a silicon oxide film, a silicon nitride film and a silicon oxide film.

Then, as shown in FIG. 5, the protective insulating film patterns 109A and 109B are removed by wet etching using a buffered hydrofluoric acid solution, for example, to expose the top surfaces of the silicon film patterns 104A and 104B except their edge parts. In this etching step, the interlayer insulating film 107 is also thinned down. Even if the interlayer insulating film 107 is etched down simultaneously with the protective insulating film patterns 109A and 109B, it is not a serious problem because the etching can be performed under control so as not to expose the surface of the semiconductor substrate 101.

In the present embodiment, the protective insulating film 109 and the interlayer insulating film 107 may be formed using materials having different etch rates or deposited under different deposition conditions to have different etch rates. For example, if the protective insulating film 109 and the interlayer insulating film 107 are both made of silicon oxide, phosphorus (P) or boron (B) may be added to silicon oxide forming the protective insulating film 109 such that the etch rate of the protective insulating film 109 (the protective insulating film patterns 109A and 109B) becomes higher than that of the interlayer insulating film 107. This makes it possible to selectively etch the protective insulating film patterns 109A and 109B relative to the interlayer insulating film 107.

In the present embodiment, in order to give etch selectivity to the silicon oxide film forming the protective insulating film patterns 109A and 109B relative to the silicon film patterns 104A and 104B and the silicon nitride film forming the sidewall spacers 105A and 105B, wet etching is performed using an etchant containing hydrofluoric acid as a main ingredient. Alternatively, dry etching is performed by reactive ion etching, e.g., by supplying C₅F₈ at a flow rate of 15 ml/min (standard conditions), O₂ at 18 ml/min (standard conditions) and Ar at 950 ml/min (standard conditions) at a pressure of 6.7 Pa, RF power of 1800 W/1500 W (T/B: top/bottom) and a substrate temperature of 0° C.

Next, in the step of FIG. 6, a 45 nm thick metallic film 110 made of nickel (Ni) is deposited on the entire surface of the semiconductor substrate 101 including the silicon film patterns 104A and 104B, for example, by sputtering.

Then, the semiconductor substrate 101 is subjected to thermal treatment in nitrogen atmosphere at 400° C., for example, by rapid thermal annealing (RTA), to cause silicidation between the silicon film patterns 104A and 104B and the metallic film 110 such that the silicon film patterns 104A and 104B are fully silicided. Thus, as shown in FIG. 7, a first gate electrode 114 and a second gate electrode 115 both having a FUSI structure and different gate lengths are provided on the semiconductor substrate 101. In this step, silicidation does not occur between the source/drain regions 106 and the metallic film 110 because the surfaces of the source/drain regions 106 are covered with the interlayer insulating film 107. Then, unreacted part of the metallic film 110 is removed by selective etching and an interlayer insulating film, contacts and wires (not shown) are formed.

As a feature of the present embodiment, the silicon film patterns 104A and 104B for forming the first and second gate electrodes 114 and 115 are fully silicided with the metallic film 110 in the silicidation step shown in FIGS. 6 and 7 while the top surfaces of the edge parts of the silicon film patterns 104A and 104B are covered with the sidewall spacers 105A and 105B. More specifically, in the silicidation step, the top surfaces of the edge parts of the silicon film patterns 104A and 104B are not in direct contact with the metallic film 110. Therefore, to the edge parts of the silicon film patterns 104A and 104B, i.e., parts of the silicon film patterns 104A and 104B adjacent to the sidewall spacers 105A and 105B, metal is not supplied from part of the metallic film 110 deposited immediately thereon, but only from part of the metallic film 110 deposited on and near the sidewall spacers 105A and 105B. As a result, the metal supplied from the part of the metallic film 110 deposited on and near the sidewall spacers 105A and 105B to the silicon film patterns 104A and 104B, which has been excess amount according to the conventional art, is consumed in the silicidation of the edge parts of the silicon film patterns 104A and 104B covered with the sidewall spacers 105A and 105B. Thus, the amount of metal supplied to parts of the silicon film patterns 104A and 104B adjacent to the sidewall spacers 105A and 105B becomes equal to the amount of metal supplied to middle parts of the silicon film patterns 104A and 104B away from the sidewall spacers 105A and 105B from the part of the metallic film 110 deposited immediately on the middle parts. Since the silicidation is performed while the top surfaces of the edge parts of the silicon film patterns 104A and 104B to be the gate electrodes 114 and 115 are covered with the sidewall spacers 105A and 105B, the interfaces between the silicon film patterns 104A and 104B and the sidewall spacers 105A and 105B are broadened, respectively, and the distance traveled by the diffusing metal along each of the interfaces is increased. This makes it possible to suppress accelerated silicidation of the parts of the silicon film patterns 104A and 104B adjacent to the sidewall spacers 105A and 105B, i.e., the gate edges. As substantially the same amount of metal is supplied to every part of the silicon film patterns 104A and 104B during the silicidation, silicide of almost the same composition is obtained in both of the parts adjacent to the sidewall spacers 105A and 105B and the middle parts away from the sidewall spacers 105A and 105B. As a result, the gate electrodes 114 and 115 are provided with a FUSI structure of substantially uniform composition in every part. This suppresses the variations in threshold voltage.

According to the conventional art, the rate of silicidation of the silicon film patterns has been determined by the progress of the silicidation of the parts of the silicon film patterns adjacent to the sidewall spacers. According to the method of the present embodiment, on the other hand, the silicidation rate is determined by the amount of metal supplied to the parts of the silicon film patterns adjacent to the sidewall spacers. Thus, the method of the present embodiment makes it possible to provide the gate electrodes 114 and 115 having different sizes such as gate lengths with a FUSI structure of uniform composition.

According to the method of the present embodiment, the silicidation of the silicon film patterns 104A and 104B which will be the gate electrodes 114 and 115 is performed while parts of the top surfaces of the silicon film patterns 104A and 104B are covered with the sidewall spacers 105A and 105B. Therefore, stress caused by expansion of the silicon film patterns 104A and 104B during the silicidation is placed on the semiconductor substrate 101. This makes it possible to improve the drive performance of the FETs 111 and 112. As the silicon film patterns 104A and 104B are obtained with the side and top surfaces of their edge parts being covered with the sidewall spacers 105A and 105B by removing the protective insulating film patterns 109A and 109B, large stress caused by the expansion of the silicon film patterns 104A and 104B during the full silicidation is placed on the semiconductor substrate 101 (channel region).

According to the method of the present embodiment, the first and second FETs 111 and 112 including the gate electrodes 114 and 115 having the FUSI structure of the same and uniform composition are simultaneously provided on the single semiconductor substrate 101.

In the present embodiment, the first and second FETs 111 and 112 are both n-FETs. However, they may be p-FETs or an n-FET and a p-FET. If the p-FET is additionally formed in the method of the present embodiment, the step of reducing the thickness of part of the silicon film 104 in the p-FET region smaller than the thickness of part of the silicon film 104 in the n-FET region is additionally performed to vary the silicide composition between the p- and n-FET regions. Even in this case, the gate electrodes having a FUSI structure of the same and uniform composition are formed in each of the FET regions.

In the present embodiment, hafnium oxide (HfO₂) is used as the material for the gate insulating film 103. However, it may be replaced with HfSiO, HfSiON, SiO₂, SiON or other suitable material.

In the present embodiment, silicon oxide is used as the material for the protective insulating film 109. However, the material for the protective insulating film 109 is not particularly limited as long as the etch selectivity relative to the sidewall spacers 105A and 105B and the silicon film 104 is surely obtained. For example, other material films such as a silicon nitride film formed by ALD (atomic layer deposition) may also be used.

In the present embodiment, nickel is used as the material for the metallic film 110. However, it may be replaced with titanium (Ti), cobalt (Co), platinum (Pt) or a compound thereof.

### Second Embodiment

Hereinafter, explanation of a semiconductor device and a method for manufacturing the same according to a second embodiment of the present invention is provided with reference to the drawings. In the present embodiment, n-FETs are formed as a first FET 211 and a second FET 212.

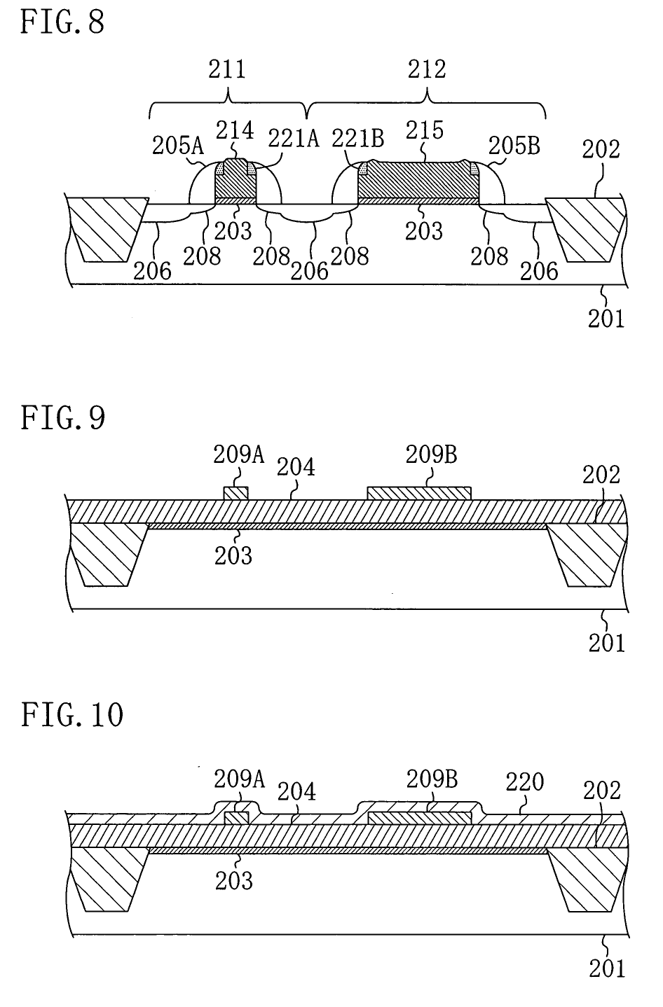

FIG. 8 shows the sectional structure of a semiconductor device according to the present embodiment. As shown in FIG. 8, for example, an isolation region 202 is formed by a STI technique in the principal surface of a semiconductor substrate 201 made of silicon (Si) to define an active region and a region for forming a resistance element. In the present embodiment, a first FET 211 and a second FET 212 having different gate lengths are formed on the active region. More specifically, the first FET 211 includes a gate insulating film 203 formed on the active region of the semiconductor substrate 201, a first gate electrode 214 formed on the gate insulating film 203 and made of FUSI metal silicide, first sidewall spacers (first external sidewall spacers) 205A formed on the side surfaces of the first gate electrode 214 and made of Si₃N₄, for example, n-type extension regions 208 formed in parts of the active region of the semiconductor substrate 201 on the sides of the first gate electrode 214 and n-type source/drain regions 206 formed in parts of the active region of the semiconductor substrate 201 on the sides of the first external sidewall spacers 205A opposite to the first gate electrode 214. The n-type extension regions 208 and the source/drain regions 206 are formed by ion implantation technique. The second FET 212 includes the gate insulating film 203 formed on the active region of the semiconductor substrate 201, a second gate electrode 215 formed on the gate insulating film 203 and made of FUSI metal silicide, second sidewall spacers (second external sidewall spacers) 205B formed on the side surfaces of the second gate electrode 215 and made of Si₃N₄, for example, n-type extension regions 208 formed in parts of the active region of the semiconductor substrate 201 on the sides of the second gate electrode 215 and n-type source/drain regions 206 formed in parts of the active region of the semiconductor substrate 201 on the sides of the second external sidewall spacers 205B opposite to the second gate electrode 215. The n-type extension regions 208 and the source/drain regions 206 are formed by ion implantation technique. The gate length of the second gate electrode 215 is larger than that of the first gate electrode 214.

As a feature of the present embodiment, the edge parts of the first gate electrode 214 are lower in height than the other part thereof and first internal sidewall spacers 221A are formed to cover the top surfaces of the edge parts and the side surfaces of the other part. Further, the edge parts of the second gate electrode 215 are lower in height than the other part thereof and second internal sidewall spacers 221B are formed to cover the top surfaces of the edge parts and the side surfaces of the other part. That is, the first and second gate electrodes 214 and 215 are substantially convex-shaped when viewed in section, respectively, as shown in FIG. 8. The first external sidewall spacers 205A of the first FET 211 cover the side surfaces of the edge parts of the first gate electrode 214 and the first internal sidewall spacers 221A. The second external sidewall spacers 205B of the first FET 212 cover the side surfaces of the edge parts of the second gate electrode 215 and the second internal sidewall spacers 221B.

According to the above-described structure of the present embodiment, the FUSI gate electrodes 214 and 215 having the same structure are provided with the same and uniform silicide composition in a self alignment manner irrespective of the sizes of the gate electrodes 214 and 215 (e.g., gate lengths) as described later. Therefore, in the gate electrodes 214 and 215 of the FETs 211 and 212, variations in silicide composition due to the difference in size between the gate electrodes 214 and 215 are prevented, and so are variations in threshold value.

According to the structure of the present embodiment, in the silicidation of the silicon film for forming the gate electrodes 214 and 215, the top surface of the silicon film is partially covered with the sidewall spacers (internal sidewall spacers) 221A and 221B. Therefore, stress caused by expansion of the silicon film during the silicidation is placed on the semiconductor substrate 201. This makes it possible to improve the drive performance of the FETs 211 and 212.

In FIG. 8, two FETs 211 and 212 are shown for convenience's sake. However, in the present embodiment, a larger number of elements may be formed on the semiconductor substrate 201. Although the first and second FETs 211 and 212 of the present embodiment are formed on the same active region surrounded by the isolation region 202, they may be formed on different active regions separated by the isolation region 202. Further, the first and second FETs 211 and 212 may be either n-FETs or p-FETs or they may be different FETs.

In the semiconductor device of the present embodiment, part of the first gate electrode 214 other than the edge parts thereof may be substantially flush with or higher or lower in height than the top end of the first internal sidewall spacers 221A. If the other part of the first gate electrode 214 than the edge parts is higher in height than the top end of the first internal sidewall spacers 221A, a portion of the other part protruding from the top end of the first internal sidewall spacers 221A may be formed wider than a portion of the other part sandwiched between the first internal sidewall spacers 221A. Likewise, part of the second gate electrode 215 other than the edge parts thereof may be substantially flush with or higher or lower in height than the top end of the second internal sidewall spacers 221B. If the other part of the second gate electrode 215 than the edge parts is higher in height than the top end of the second internal sidewall spacers 221B, a portion of the other part protruding from the top end of the second internal sidewall spacers 221B may be formed wider than a portion of the other part sandwiched between the second internal sidewall spacers 221B.

If the FUSI structure of the gate electrodes 214 and 215 of the semiconductor device of the present embodiment is applied to a resistance element or an upper electrode of a capacitative element, a fuse element or the like, the resistance element, the upper electrode of the capacitative element, the fuse element or the like is also achieved with the FUSI structure of uniform composition.

Now, a method for manufacturing the semiconductor device of the present embodiment shown in FIG. 8 is explained with reference to the drawings. FIGS. 9 to 16 are sectional views sequentially illustrating the steps of the method for manufacturing the semiconductor device of the present embodiment. In FIGS. 9 to 16, the same components as those of the semiconductor device shown in FIG. 8 are indicated by the same reference numerals to omit overlapping explanation.

First, as shown in FIG. 9, for example, an isolation region 202 is formed by a STI technique in an upper portion of a semiconductor substrate 201 made of silicon and ion implantation is performed to form a well and a channel stopper (not shown). As a result, a region of the semiconductor substrate 201 surrounded by the isolation region 202 is defined as an active region. A gate insulating film 203 made of HfO₂ is deposited on the active region of the principal surface of the semiconductor substrate 201 by CVD up to a physical thickness of about 3 nm, for example. Then, an about 75 nm thick polysilicon film and an about 25 nm thick SiO₂ film, for example, are deposited in this order by CVD on the semiconductor substrate 201 (on the active region with the gate insulating film 203 interposed therebetween) as a silicon film 204 and a protective insulating film 209, respectively. The silicon film 204 may be an amorphous silicon film or implanted with impurities. Then, a resist pattern (not shown) covering a region for forming gate electrodes is formed on the protective insulating film 209 by lithography and the protective insulating film 209 is patterned into the form of a first gate electrode 214 and a second gate electrode 215 by etching using the resist pattern as a mask. Thus, a first protective insulating film pattern 209A and a second protective insulating film pattern 209B are obtained. In the lithography step, part of the resist pattern corresponding to the first protective insulating film pattern 209A is configured to have a width smaller than the width of the first gate electrode 214 by about 10 nm, for example, reduced from each of the edges of the first gate electrode 214. Simultaneously, part of the resist pattern corresponding to the second protective insulating film pattern 209B is configured to have a width smaller than the width of the second gate electrode 215 by about 10 nm, for example, reduced from each of the edges of the second gate electrode 215. For example, if the etching is performed by dry etching, an etching gas containing fluorocarbon as a main ingredient may be used.

Then, as shown in FIG. 10, for example, a 10 nm thick oxide film is deposited as an insulating film 220 by CVD on the silicon film 204 including the protective insulating film patterns 209A and 209B.

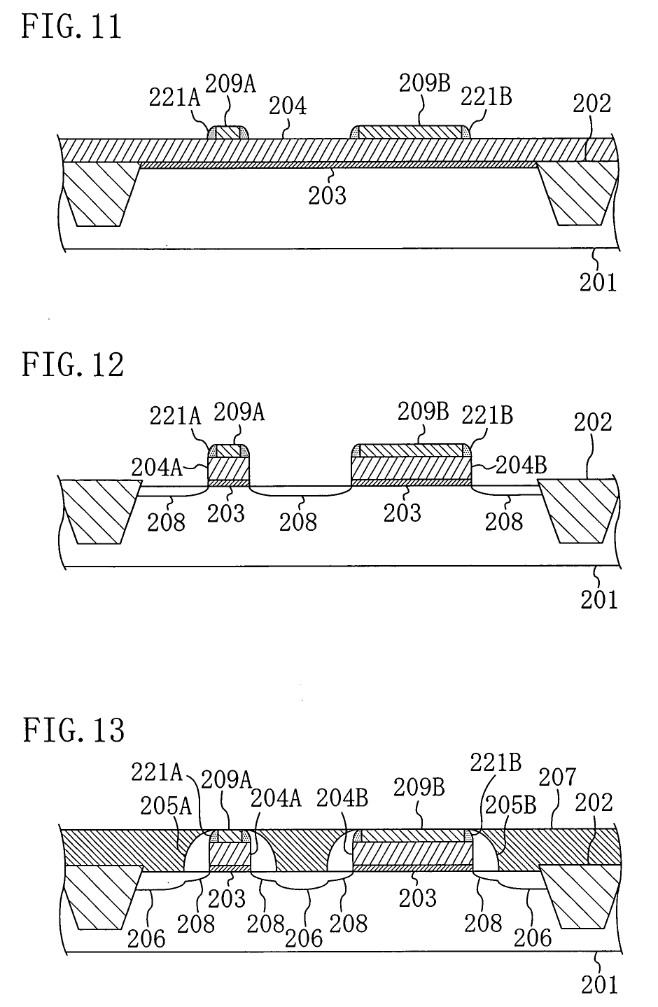

Then, as shown in FIG. 11, the insulating film 220 is etched back to form first internal sidewall spacers 221A covering the top surfaces of parts of the silicon film 204 to be the edge parts of the first gate electrode 214 and the side surfaces of the first protective insulating film pattern 209A. Simultaneously, second internal sidewall spacers 221B are formed to cover the top surfaces of parts of the silicon film 204 to be the edge parts of the second gate electrode 215 and the side surfaces of the second protective insulating film pattern 209B.

The internal sidewall spacers 221A and 221B of the present embodiment are formed as a single layer structure made of the insulating film 220. However, they may be formed as a two-layer structure made of a silicon oxide film and a silicon nitride film or a three-layer structure made of a silicon oxide film, a silicon nitride film and a silicon oxide film.

Then, using the protective insulating film patterns 209A and 209B and the internal sidewall spacers 221A and 221B as a mask, the silicon film 204 is patterned into the form of a first gate electrode 214 and a second gate electrode 215 by etching. Thus, first and second silicon film patterns 204A and 204B having different gate lengths are obtained as shown in FIG. 12. If the etching is performed by dry etching, an etching gas containing chlorine as a main ingredient may be used, for example. Then, using the protective insulating film patterns 209A and 209B and the internal sidewall spacers 221A and 221B as a mask, ion implantation is performed to form n-type extension regions 208 in the active region in the surface of the semiconductor substrate 201.

Then, a silicon nitride film is deposited on the entire surface of the semiconductor substrate 201, for example, by CVD, and etched back to form first external sidewall spacers 205A covering the side surfaces of the first silicon film pattern 204A and the first internal sidewall spacers 221A and second external sidewall spacers 205B covering the side surfaces of the second silicon film pattern 204B and the second internal sidewall spacers 221B as shown in FIG. 13. Subsequently, using the external sidewall spacers 205A and 205B, the internal sidewall spacers 221A and 221B and the protective insulating film patterns 209A and 209B as a mask, impurities are implanted into the semiconductor substrate 201 to form n-type source/drain regions 206. An interlayer insulating film 207 is then deposited on the entire surface of the semiconductor substrate 201 and planarized by CMP, for example, to expose the top surfaces of the protective insulating film patterns 209A and 209B.

Though not shown, the surfaces of the n-type source/drain regions 206 formed in the step of FIG. 13 may be silicided with nickel (Ni) or the like. In this step, the silicon film patterns 204A and 204B which will be the gate electrodes 214 and 215 are not silicided because they are covered with the external sidewall spacers 205A and 205B, the internal sidewall spacers 221A and 221B and the protective insulating film patterns 209A and 209B.

The external sidewall spacers 205A and 205B of the present embodiment are formed as a single layer structure made of a silicon nitride film. However, they may be formed as a two-layer structure made of a silicon oxide film and a silicon nitride film or a three-layer structure made of a silicon oxide film, a silicon nitride film and a silicon oxide film.

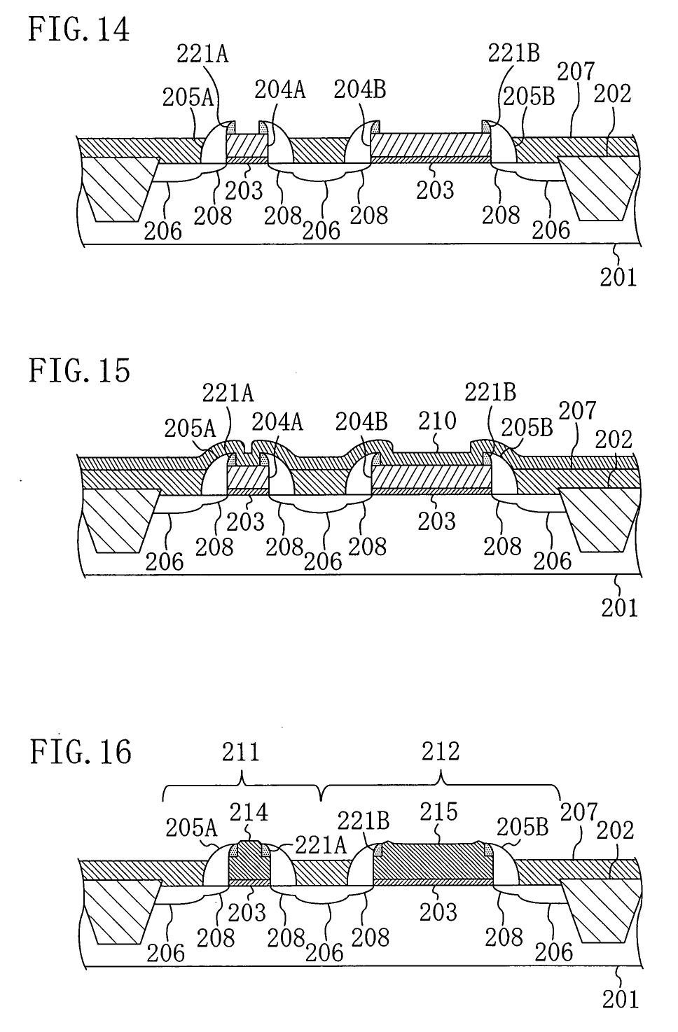

Then, as shown in FIG. 14, the protective insulating film patterns 209A and 209B are removed by wet etching using a buffered hydrofluoric acid solution, for example, to expose the top surfaces of the silicon film patterns 204A and 204B except their edge parts. In this etching step, the interlayer insulating film 207 is also thinned down. Even if the interlayer insulating film 207 is etched down simultaneously with the protective insulating film patterns 209A and 209B, it is not a serious problem because the etching can be performed under control so as not to expose the surface of the semiconductor substrate 201.

In the present embodiment, the protective insulating film 209 and the interlayer insulating film 207 may be formed using materials having different etch rates or deposited under different deposition conditions to have different etch rates. For example, if the protective insulating film 209 and the interlayer insulating film 207 are both made of silicon oxide, phosphorus (P) or boron (B) may be added to silicon oxide forming the protective insulating film 209 such that the etch rate of the protective insulating film 209 (the protective insulating film patterns 209A and 209B) becomes higher than that of the interlayer insulating film 207. This makes it possible to selectively etch the protective insulating film pattern 209A and 209B relative to the interlayer insulating film 207.

In the present embodiment, in order to give etch selectivity to the silicon oxide film forming the protective insulating film patterns 209A and 209B relative to the silicon film patterns 204A and 204B and the silicon nitride film forming the external sidewall spacers 205A and 205B and the internal sidewall spacers 221A and 221B, wet etching is performed using an etchant containing hydrofluoric acid as a main ingredient. Alternatively, dry etching is performed by reactive ion etching, e.g., by supplying C₅F₈ at a flow rate of 15 ml/min (standard conditions), O₂ at 18 ml/min (standard conditions) and Ar at 950 ml/min (standard conditions) at a pressure of 6.7 Pa, RF power of 1800 W/1500 W (T/B: top/bottom) and a substrate temperature of 0° C.

Next, in the step of FIG. 15, a 45 nm thick metallic film 210 made of nickel (Ni) is deposited on the entire surface of the semiconductor substrate 201 including the silicon film patterns 204A and 204B, for example, by sputtering.

Then, the semiconductor substrate 201 is subjected to thermal treatment in nitrogen atmosphere at 400° C., for example, by RTA, to cause silicidation between the silicon film patterns 204A and 204B and the metallic film 210 such that the silicon film patterns 204A and 204B are fully silicided. Thus, as shown in FIG. 16, a first gate electrode 214 and a second gate electrode 215 both having a FUSI structure and different gate lengths are provided on the semiconductor substrate 201. In this step, silicidation does not occur between the source/drain regions 206 and the metallic film 210 because the surfaces of the source/drain regions 206 are covered with the interlayer insulating film 207. Then, unreacted part of the metallic film 210 is removed by selective etching and an interlayer insulating film, contacts and wires (not shown) are formed.

As a feature of the present embodiment, the silicon film patterns 204A and 204B for forming the first and second gate electrodes 214 and 215 are fully silicided with the metallic film 210 in the silicidation step shown in FIGS. 15 and 16 while the top surfaces of the edge parts of the silicon film patterns 204A and 204B are covered with the internal sidewall spacers 221A and 221B. More specifically, in the silicidation step, the top surfaces of the edge parts of the silicon film patterns 204A and 204B are not in direct contact with the metallic film 210. Therefore, to the edge parts of the silicon film patterns 204A and 204B, i.e., parts of the silicon film patterns 204A and 204B adjacent to the sidewall spacers 205A and 205B, metal is not supplied from part of the metallic film 210 deposited immediately thereon, but only from part of the metallic film 210 deposited on and near the internal sidewall spacers 221A and 221B. As a result, the metal supplied from the part of the metallic film 210 deposited on and near the internal sidewall spacers 221A and 221B to the silicon film patterns 204A and 204B, which has been excess amount according to the conventional art, is consumed in the silicidation of the edge parts of the silicon film patterns 204A and 204B covered with the internal sidewall spacers 221A and 221B. Thus, the amount of metal supplied to parts of the silicon film patterns 204A and 204B adjacent to the external sidewall spacers 205A and 205B becomes equal to the amount of metal supplied to middle parts of the silicon film patterns 204A and 204B away from the external sidewall spacers 205A and 205B from the part of the metallic film 210 deposited immediately on the middle parts. Since the silicidation is performed while the top surfaces of the edge parts of the silicon film patterns 204A and 204B to be the gate electrodes 214 and 215 are covered with the internal sidewall spacers 221A and 221B, the interfaces of the silicon film patterns 204A and 204B with the external sidewall spacers 205A and 205B and the internal sidewall spacers 221A and 221B are broadened, respectively, and the distance traveled by the diffusing metal along each of the interfaces is increased. This makes it possible to suppress accelerated silicidation of the parts of the silicon film patterns 204A and 204B adjacent to the external sidewall spacers 205A and 205B, i.e., the gate edges. As substantially the same amount of metal is supplied to every part of the silicon film patterns 204A and 204B during the silicidation, silicide of almost the same composition is obtained in both of the parts adjacent to the external sidewall spacers 205A and 205B and the middle parts away from the external sidewall spacers 205A and 205B. As a result, the gate electrodes 214 and 215 are provided with a FUSI structure of substantially uniform composition in every part. This suppresses the variations in threshold voltage.

According to the conventional art, the rate of silicidation of the silicon film patterns has been determined by the progress of the silicidation of the parts of the silicon film patterns adjacent to the sidewall spacers. According to the method of the present embodiment, on the other hand, the silicidation rate is determined by the amount of metal supplied to the parts of the silicon film patterns adjacent to the sidewall spacers. Thus, the method of the present embodiment makes it possible to provide the gate electrodes 214 and 215 having different sizes such as gate lengths with a FUSI structure of uniform composition.

According to the method of the present embodiment, the silicidation of the silicon film patterns 204A and 204B which will be the gate electrodes 214 and 215 is performed while parts of the top surfaces of the silicon film patterns 204A and 204B are covered with the internal sidewall spacers 221A and 221B. Therefore, stress caused by expansion of the silicon film patterns 204A and 204B during the silicidation is placed on the semiconductor substrate 201. This makes it possible to improve the drive performance of the FETs 211 and 212.

According to the method of the present embodiment, the widths of the top surfaces of the edge parts of the silicon film patterns 204A and 204B to be covered with the internal sidewall spacers 221A and 221B are easily controlled by controlling the thickness of the internal sidewall spacers 221A and 221B.

Further, according to the method of the present embodiment, the first and second FETs 211 and 212 including the gate electrodes 214 and 215 having the FUSI structure of the same and uniform composition are simultaneously provided on the single semiconductor substrate 201.

In the present embodiment, the first and second FETs 211 and 212 are both n-FETs. However, they may be p-FETs or an n-FET and a p-FET. If the p-FET is additionally formed in the method of the present embodiment, the step of reducing the thickness of part of the silicon film 204 in the p-FET region smaller than the thickness of part of the silicon film 204 in the n-FET region is additionally performed to vary the silicide composition between the p- and n-FET regions. Even in this case, the gate electrodes having a FUSI structure of the same and uniform composition are formed in each of the FET regions.

In the present embodiment, hafnium oxide (HfO₂) is used as the material for the gate insulating film 203. However, it may be replaced with HfSiO, HfSiON, SiO₂, SiON or other suitable material.

In the present embodiment, silicon oxide is used as the material for the protective insulating film 209. However, the material for the protective insulating film 209 is not particularly limited as long as the etch selectivity relative to the external sidewall spacers 205A and 205B, the internal sidewall spacers 221A and 221B and the silicon film 204 is surely obtained. For example, other material films such as a silicon nitride film formed by ALD (atomic layer deposition) may also be used.

In the present embodiment, nickel is used as the material for the metallic film 210. However, it may be replaced with titanium (Ti), cobalt (Co), platinum (Pt) or a compound thereof.

### Third Embodiment

Hereinafter, explanation of a semiconductor device and a method for manufacturing the same according to a third embodiment of the present invention is provided with reference to the drawings. In the present embodiment, n-FETs are formed as a first FET 311 and a second FET 312.

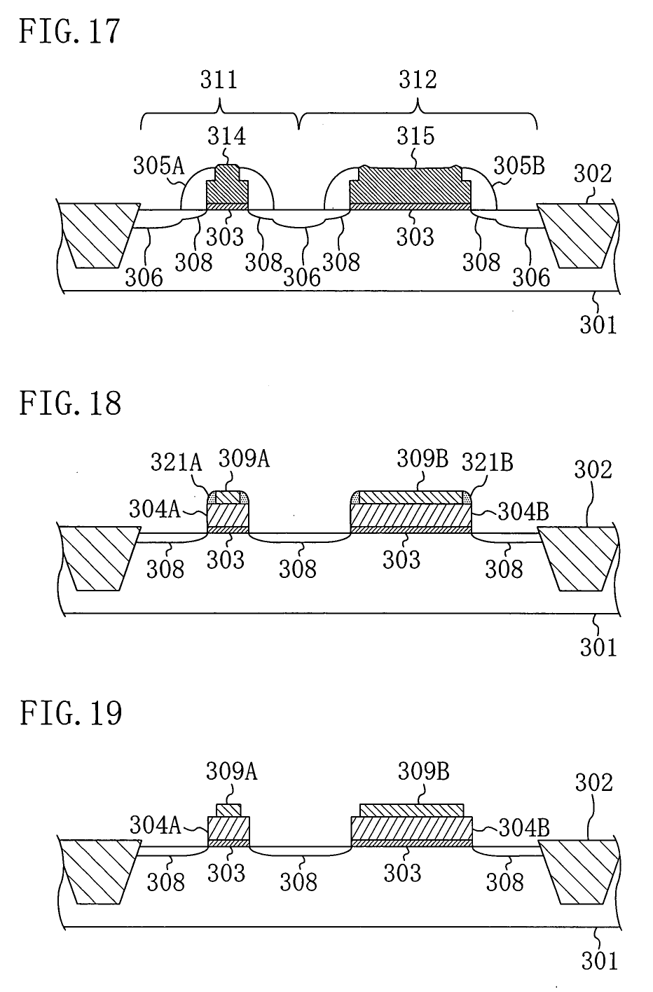

FIG. 17 shows the sectional structure of a semiconductor device according to the present embodiment. As shown in FIG. 17, for example, an isolation region 302 is formed by a STI technique in the principal surface of a semiconductor substrate 301 made of silicon (Si) to define an active region and a region for forming a resistance element. In the present embodiment, a first FET 311 and a second FET 312 having different gate lengths are formed on the active region. More specifically, the first FET 311 includes a gate insulating film 303 formed on the active region of the semiconductor substrate 301, a first gate electrode 314 formed on the gate insulating film 303 and made of FUSI metal silicide, first sidewall spacers 305A formed on the side surfaces of the first gate electrode 314 and made of Si₃N₄, for example, n-type extension regions 308 formed in parts of the active region of the semiconductor substrate 301 on the sides of the first gate electrode 314 and n-type source/drain regions 306 formed in parts of the active region of the semiconductor substrate 301 on the sides of the first sidewall spacers 305A opposite to the first gate electrode 314. The n-type extension regions 308 and the source/drain regions 306 are formed by ion implantation technique. The second FET 312 includes the gate insulating film 303 formed on the active region of the semiconductor substrate 301, a second gate electrode 315 formed on the gate insulating film 303 and made of FUSI metal silicide, second sidewall spacers 305B formed on the side surfaces of the second gate electrode 315 and made of Si₃N₄, for example, n-type extension regions 308 formed in parts of the active region of the semiconductor substrate 301 on the sides of the second gate electrode 315 and n-type source/drain regions 306 formed in parts of the active region of the semiconductor substrate 301 on the sides of the second sidewall spacers 305B opposite to the second gate electrode 315. The n-type extension regions 308 and the source/drain regions 306 are formed by ion implantation technique. The gate length of the second gate electrode 315 is larger than that of the first gate electrode 314.

As a feature of the present embodiment, the edge parts of the first gate electrode 314 are lower in height than the other part thereof and the first sidewall spacers 305A are formed to cover the side and top surfaces of the edge parts. Further, the edge parts of the second gate electrode 315 are lower in height than the other part thereof and the second sidewall spacers 305B are formed to cover the side and top surfaces of the edge parts. That is, the first and second gate electrodes 314 and 315 are substantially convex-shaped when viewed in section, respectively, as shown in FIG. 17.

According to the above-described structure of the present embodiment, the FUSI gate electrodes 314 and 315 having the same structure are provided with the same and uniform silicide composition in a self alignment manner irrespective of the sizes of the gate electrodes 314 and 315 (e.g., gate lengths) as described later. Therefore, in the gate electrodes 314 and 315 of the FETs 311 and 312, variations in silicide composition due to the difference in size between the gate electrodes 314 and 315 are prevented, and so are variations in threshold value.

According to the structure of the present embodiment, in the silicidation of the silicon film for forming the gate electrodes 314 and 315, the top surface of the silicon film is partially covered with the sidewall spacers 305A and 305B. Therefore, stress caused by expansion of the silicon film during the silicidation is placed on the semiconductor substrate 301. This makes it possible to improve the drive performance of the FETs 311 and 312.

In FIG. 17, two FETs 311 and 312 are shown for convenience's sake. However, in the present embodiment, a larger number of elements may be formed on the semiconductor substrate 301. Although the first and second FETs 311 and 312 of the present embodiment are formed on the same active region surrounded by the isolation region 302, they may be formed on different active regions separated by the isolation region 302. Further, the first and second FETs 311 and 312 may be either n-FETs or p-FETs or they may be different FETs.

In the semiconductor device of the present embodiment, part of the first gate electrode 314 other than the edge parts thereof may be substantially flush with or higher or lower in height than the top end of the first sidewall spacers 305A. If the other part of the first gate electrode 314 than the edge parts is higher in height than the top end of the first sidewall spacers 305A, a portion of the other part protruding from the top end of the first sidewall spacers 305A may be formed wider than a portion of the other part sandwiched between the first sidewall spacers 305A. Likewise, part of the second gate electrode 315 other than the edge parts thereof may be substantially flush with or higher or lower in height than the top end of the second sidewall spacers 305B. If the other part of the second gate electrode 315 than the edge parts is higher in height than the top end of the second sidewall spacers 305B, a portion of the other part protruding from the top end of the second sidewall spacers 305B may be formed wider than a portion of the other part sandwiched between the second sidewall spacers 305B.

If the FUSI structure of the gate electrodes 314 and 315 of the semiconductor device of the present embodiment is applied to a resistance element, an upper electrode of a capacitative element, a fuse element or the like, the resistance element, the upper electrode of the capacitative element, the fuse element or the like is also achieved with the FUSI structure of uniform composition.

Now, a method for manufacturing the semiconductor device of the present embodiment shown in FIG. 17 is explained with reference to the drawings. FIGS. 18 to 23 are sectional views sequentially illustrating the steps of the method for manufacturing the semiconductor device of the present embodiment. In FIGS. 18 to 23, the same components as those of the semiconductor device shown in FIG. 17 are indicated by the same reference numerals to omit overlapping explanation.

In the method of the present embodiment, the same steps as those of the second embodiment shown in FIGS. 9 to 12 are performed.

More specifically, as shown in FIG. 18, for example, an isolation region 302 is formed by a STI technique in an upper portion of a semiconductor substrate 301 made of silicon and ion implantation is performed to form a well and a channel stopper (not shown). As a result, a region of the semiconductor substrate 301 surrounded by the isolation region 302 is defined as an active region. A gate insulating film 303 made of hafnium oxide (HfO₂) is deposited on the active region of the principal surface of the semiconductor substrate 301 by CVD up to a physical thickness of about 3 nm, for example. Then, an about 75 nm thick polysilicon film and an about 25 nm thick SiO₂ film, for example, are deposited in this order by CVD on the semiconductor substrate 301 (on the active region with the gate insulating film 303 interposed therebetween) as a silicon film 304 and a protective insulating film 309, respectively. The silicon film 304 may be an amorphous silicon film or implanted with impurities. Then, a resist pattern (not shown) covering a region for forming gate electrodes is formed on the protective insulating film 309 by lithography and the protective insulating film 309 is patterned into the form of a first gate electrode 314 and a second gate electrode 315 by etching using the resist pattern as a mask. Thus, a first protective insulating film pattern 309A and a second protective insulating film pattern 309B are obtained. In the lithography step, part of the resist pattern corresponding to the first protective insulating film pattern 309A is configured to have a width smaller than the width of the first gate electrode 314 by about 10 nm, for example, reduced from each of the edges of the first gate electrode 314. Simultaneously, part of the resist pattern corresponding to the second protective insulating film pattern 309B is configured to have a width smaller than the width of the second gate electrode 315 by about 10 nm, for example, reduced from each of the edges of the second gate electrode 315. If the etching is performed by dry etching, an etching gas containing fluorocarbon as a main ingredient may be used.

Then, a 10 nm thick oxide film (a silicon oxide film added with phosphorus (P) or boron (B)) is deposited as an insulating film by CVD, for example, on the silicon film 304 including the protective insulating film patterns 309A and 309B. Then, the insulating film is etched back to form first dummy sidewall spacers 321A covering the top surfaces of parts of the silicon film 304 to be the edge parts of the first gate electrode 314 and the side surfaces of the first protective insulating film pattern 309A. Simultaneously, second dummy sidewall spacers 321B are formed to cover the top surfaces of parts of the silicon film 304 to be the edge parts of the second gate electrode 315 and the side surfaces of the second protective insulating film pattern 309B.

Then, using the protective insulating film patterns 309A and 309B and the dummy sidewall spacers 321A and 321B as a mask, the silicon film 304 is patterned into the form of a first gate electrode 314 and a second gate electrode 315 by etching. Thus, first and second silicon film patterns 304A and 304B having different gate lengths are obtained as shown in FIG. 18. If the etching is performed by dry etching, an etchant gas containing chlorine as a main ingredient may be used. Then, using the protective insulating film patterns 309A and 309B and the dummy sidewall spacers 321A and 321B as a mask, ion implantation is performed to form n-type extension regions 308 in the active region in the surface of the semiconductor substrate 301.

Then, as shown in FIG. 19, the dummy sidewall spacers 321A and 321B are removed by wet etching using an etchant containing hydrofluoric acid as a main ingredient, for example, to expose the top surfaces of the edge parts of the first and second silicon film patterns 304A and 304B. In this step, it is preferable to increase the difference in etch rate between the dummy sidewall spacers 321A and 321B and the protective insulating film patterns 309A and 309B and the insulating film as the isolation region 302 from the aspect of control of the thicknesses of the protective insulating film patterns 309A and 309B and the insulating film as the isolation region 302. More specifically, the difference in etch rate is increased by using, for example, an oxide film such as a silicon oxide film added with phosphorus (P) or boron (B), as the dummy sidewall spacers 321A and 321B.

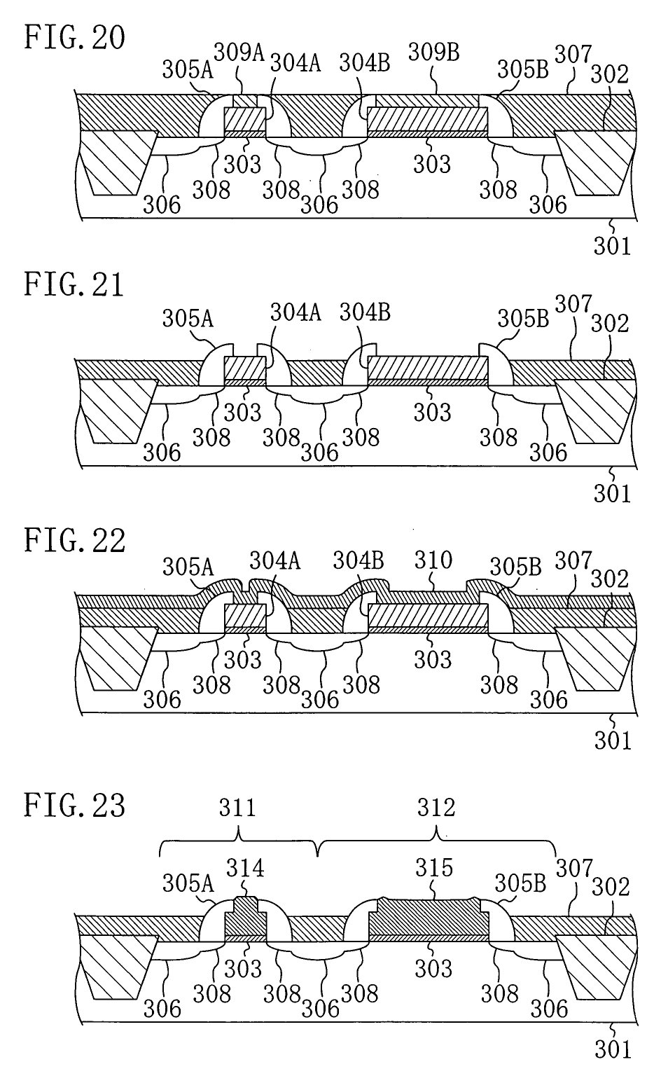

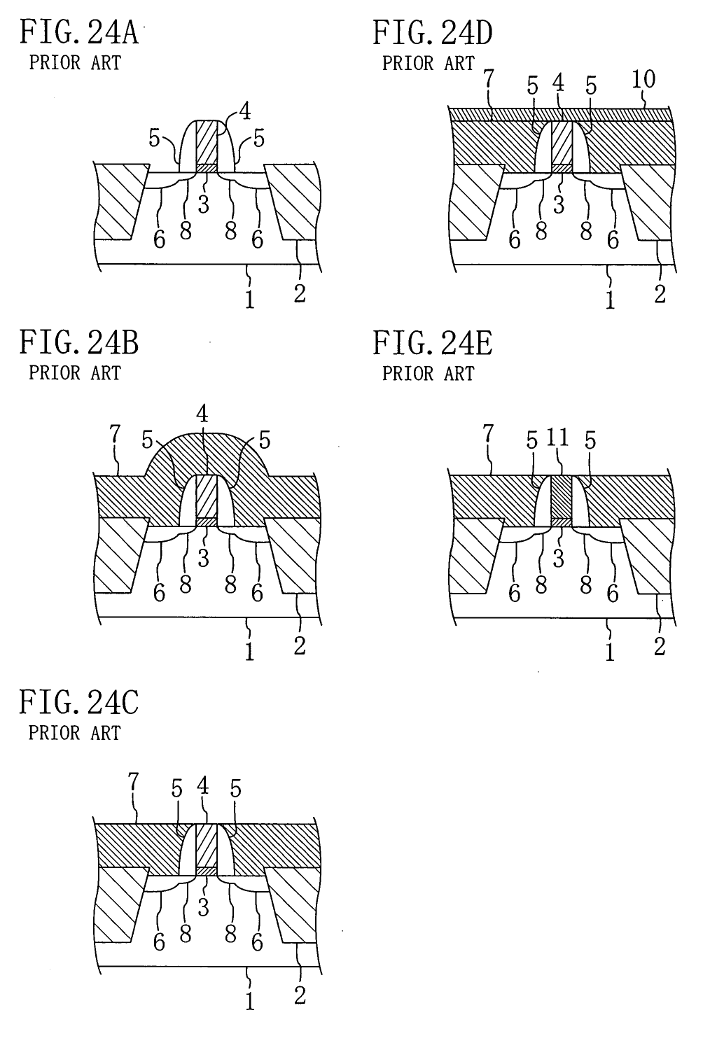

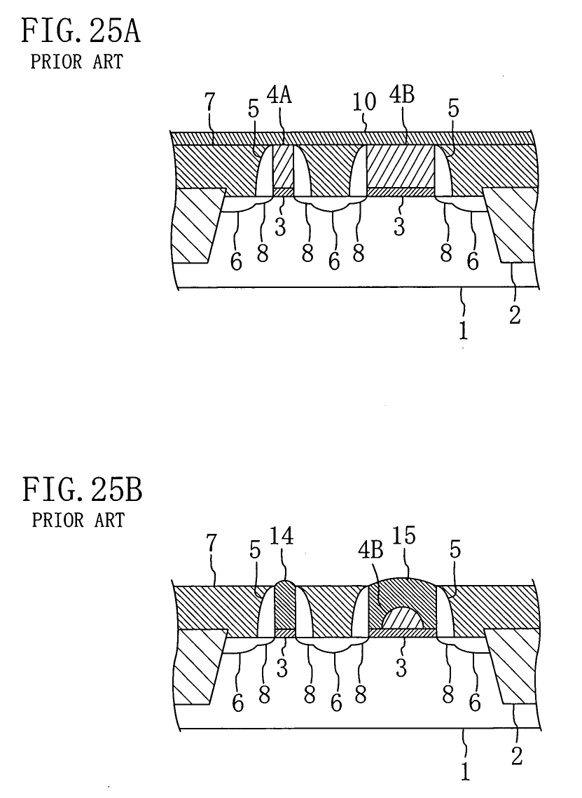

Then, a silicon nitride film is deposited on the entire surface of the semiconductor substrate 301, for example, by CVD, and etched back to form first sidewall spacers 305A on the side surfaces of the first silicon film pattern 304A and second sidewall spacers 305B on the side surfaces of the second silicon film pattern 304B as shown in FIG. 20. In this step, the edge parts of the silicon film patterns 304A and 304B are not covered with the protective insulating film patterns 309A and 309B. Therefore, the top surfaces of the edge parts of the silicon film patterns 304A and 304B are also covered with the sidewall spacers 305A and 305B. Subsequently, using the sidewall spacers 305A and 305B and the protective insulating film patterns 309A and 309B as a mask, impurities are implanted into the semiconductor substrate 301 to form n-type source/drain regions 306. An interlayer insulating film 307 is then deposited on the entire surface of the semiconductor substrate 301 and planarized by CMP, for example, to expose the top surfaces of the protective insulating film patterns 309A and 309B.

Though not shown, the surfaces of the n-type source/drain regions 306 formed in the step of FIG. 20 may be silicided with nickel (Ni) or the like. In this step, the silicon film patterns 304A and 304B which will be the gate electrodes 314 and 315 are not silicided because they are covered with the sidewall spacers 305A and 305B and the protective insulating film patterns 309A and 309B.

The sidewall spacers 305A and 305B of the present embodiment are formed as a single layer structure made of a silicon nitride film. However, they may be formed as a two-layer structure made of a silicon oxide film and a silicon nitride film or a three-layer structure made of a silicon oxide film, a silicon nitride film and a silicon oxide film.

Then, as shown in FIG. 21, the protective insulating film patterns 309A and 309B are removed by wet etching using a buffered hydrofluoric acid solution, for example, to expose the top surfaces of the silicon film patterns 304A and 304B except their edges. In this etching step, the interlayer insulating film 307 is also thinned down. Even if the interlayer insulating film 307 is etched down simultaneously with the protective insulating film patterns 309A and 309B, it is not a serious problem because the etching can be performed under control so as not to expose the surface of the semiconductor substrate 301.

In the present embodiment, the protective insulating film 309 and the interlayer insulating film 307 may be formed using materials having different etch rates or deposited under different deposition conditions to have different etch rates. For example, if the protective insulating film 309 and the interlayer insulating film 307 are both made of silicon oxide, phosphorus (P) or boron (B) may be added to silicon oxide forming the protective insulating film 309 such that the etch rate of the protective insulating film 309 (the protective insulating film patterns 309A and 309B) becomes higher than that of the interlayer insulating film 307. This makes it possible to selectively etch the protective insulating film pattern 309A and 309B relative to the interlayer insulating film 307.

In the present embodiment, in order to give etch selectivity to the silicon oxide film forming the protective insulating film patterns 309A and 309B relative to the silicon film patterns 304A and 304B and the silicon nitride film forming the sidewall spacers 305A and 305B, wet etching is performed using an etchant containing hydrofluoric acid as a main ingredient. Alternatively, dry etching is performed by reactive ion etching, e.g., by supplying C₅F₈ at a flow rate of 15 ml/min (standard conditions), O₂ at 18 ml/min (standard conditions) and Ar at 950 ml/min (standard conditions) at a pressure of 6.7 Pa, RF power of 1800 W/1500 W (T/B: top/bottom) and a substrate temperature of 0° C.

Next, in the step of FIG. 22, a 45 nm thick metallic film 310 made of nickel (Ni) is deposited on the entire surface of the semiconductor substrate 301 including the silicon film patterns 304A and 304B, for example, by sputtering.

Then, the semiconductor substrate 301 is subjected to thermal treatment in nitrogen atmosphere at 400° C., for example, by RTA, to cause silicidation between the silicon film patterns 304A and 304B and the metallic film 310 such that the silicon film patterns 304A and 304B are fully silicided. Thus, as shown in FIG. 23, a first gate electrode 314 and a second gate electrode 315 both having a FUSI structure and different gate lengths are provided on the semiconductor substrate 301. In this step, silicidation does not occur between the source/drain regions 306 and the metallic film 310 because the surfaces of the source/drain regions 306 are covered with the interlayer insulating film 307. Then, unreacted part of the metallic film 310 is removed by selective etching and an interlayer insulating film, contacts and wires (not shown) are formed.

As a feature of the present embodiment, the silicon film patterns 304A and 304B for forming the first and second gate electrodes 314 and 315 are fully silicided with the metallic film 310 in the silicidation step shown in FIGS. 22 and 23 while the top surfaces of the edge parts of the silicon film patterns 304A and 304B are covered with the sidewall spacers 305A and 305B. More specifically, in the silicidation step, the top surfaces of the edge parts of the silicon film patterns 304A and 304B are not in direct contact with the metallic film 310. Therefore, to the edge parts of the silicon film patterns 304A and 304B, i.e., parts of the silicon film patterns 304A and 304B adjacent to the sidewall spacers 305A and 305B, metal is not supplied from part of the metallic film 310 deposited immediately thereon, but only from part of the metallic film 310 deposited on and near the sidewall spacers 305A and 305B. As a result, the metal supplied from the part of the metallic film 310 deposited on and near the sidewall spacers 305A and 305B to the silicon film patterns 304A and 304B, which has been excess amount in the conventional art, is consumed in the silicidation of the edge parts of the silicon film patterns 304A and 304B covered with the sidewall spacers 305A and 305B. Thus, the amount of metal supplied to parts of the silicon film patterns 304A and 304B adjacent to the sidewall spacers 305A and 305B becomes equal to the amount of metal supplied to middle parts of the silicon film patterns 304A and 304B away from the external sidewall spacers 305A and 305B from the part of the metallic film immediately on the middle parts. Since the silicidation is performed while the top surfaces of the edge parts of the silicon film patterns 304A and 304B to be the gate electrodes 314 and 315 are covered with the sidewall spacers 305A and 305B, the interfaces between the silicon film patterns 304A and 304B and the sidewall spacers 305A and 305B are broadened, respectively, and the distance traveled by the diffusing metal along each of the interfaces is increased. This makes it possible to suppress accelerated silicidation of the parts of the silicon film patterns 304A and 304B adjacent to the sidewall spacers 305A and 305B, i.e., the gate edges. As substantially the same amount of metal is supplied to every part of the silicon film patterns 304A and 304B during the silicidation, silicide of almost the same composition is obtained in both of the parts adjacent to the sidewall spacers 305A and 305B and the middle parts away from the sidewall spacers 305A and 305B. As a result, the gate electrodes 314 and 315 are provided with a FUSI structure of substantially uniform composition in every part. This suppresses the variations in threshold voltage.

According to the conventional art, the rate of silicidation of the silicon film patterns has been determined by the progress of the silicidation of the parts of the silicon film patterns adjacent to the sidewall spacers. According to the method of the present embodiment, on the other hand, the silicidation rate is determined by the amount of metal supplied to the parts of the silicon film patterns adjacent to the sidewall spacers. Thus, the method of the present embodiment makes it possible to provide the gate electrodes 314 and 315 having different sizes such as gate lengths with a FUSI structure of uniform composition.

According to the method of the present embodiment, the silicidation of the silicon film patterns 304A and 304B which will be the gate electrodes 314 and 315 is performed while parts of the top surfaces of the silicon film patterns 304A and 304B are covered with the sidewall spacers 305A and 305B. Therefore, stress caused by expansion of the silicon film patterns 304A and 304B during the silicidation is placed on the semiconductor substrate 301. This makes it possible to improve the drive performance of the FETs 311 and 312. Further, as the side and top surfaces of the edge parts of the first silicon film patterns 304A and 304B are covered with the sidewall spacers 305A and 305B, large stress caused by the full silicidation of the silicon film patterns 304A and 304B is effectively applied to the semiconductor substrate 301 (channel region).

According to the method of the present embodiment, the widths of the top surfaces of the edge parts of the silicon film patterns 304A and 304B covered with the sidewall spacers 305A and 305B to be formed later are easily controlled by controlling the thickness of the dummy sidewall spacers 321A and 321B.

Further, according to the method of the present embodiment, the first and second FETs 311 and 312 including the gate electrodes 314 and 315 having the FUSI structure of the same and uniform composition are simultaneously provided on the single semiconductor substrate 301.

In the present embodiment, the first and second FETs 311 and 312 are both n-FETs. However, they may be p-FETs or an n-FET and a p-FET. If the p-FET is additionally formed in the method of the present embodiment, the step of reducing the thickness of part of the silicon film 304 in the p-FET region smaller than the thickness of part of the silicon film 304 in the n-FET region is additionally performed to vary the silicide composition between the p- and n-FET regions. Even in this case, the gate electrodes having a FUSI structure of the same and uniform composition are formed in each of the FET regions.

In the present embodiment, hafnium oxide (HfO₂) is used as the material for the gate insulating film 303. However, it may be replaced with HfSiO, HfSiON, SiO₂, SiON or other suitable material.

In the present embodiment, silicon oxide is used as the material for the protective insulating film 309. However, the material for the protective insulating film 309 is not particularly limited as long as the etch selectivity relative to the sidewall spacers 305A and 305B and the silicon film 304 is surely obtained. For example, other material films such as a silicon nitride film formed by ALD (atomic layer deposition) may also be used.

In the present embodiment, nickel is used as the material for the metallic film 310. However, it may be replaced with titanium (Ti), cobalt (Co), platinum (Pt) or a compound thereof.

It should be noted that the present invention is not limited to the above embodiments and various modifications are possible within the spirit and essential features of the present invention. The above embodiments shall be interpreted as illustrative and not in a limiting sense. The scope of the present invention is specified only by the following claims and the description of the specification is not limitative at all. Further, it is also to be understood that all the changes and modifications made within the scope of the claims fall within the scope of the present invention.

What is claimed is:

1. A semiconductor device comprising a first MIS transistor having a first gate electrode which is fully silicided with metal, wherein
edge parts of the first gate electrode are lower in height than the other part thereof and
first sidewall spacers are formed to cover side and top surfaces of the edge parts of the first gate electrode.

2. The semiconductor device of claim 1, wherein
the first gate electrode is convex-shaped when viewed in section.

3. The semiconductor device of claim 1, wherein
the first sidewall spacers include first internal sidewall spacers covering the top surfaces of the edge parts of the first gate electrode and side surfaces of the other part of the first gate electrode and first external sidewall spacers covering the side surfaces of the edge parts of the first gate electrode and the first internal sidewall spacers.

4. The semiconductor device of claim 1 further comprising a second MIS transistor having a second gate electrode which is fully silicided with metal and has a gate length larger than that of the first gate electrode, wherein
edge parts of the second gate electrode are lower in height than the other part thereof and
second sidewall spacers are formed to cover side and top surfaces of the edge parts of the second gate electrode.

5. The semiconductor device of claim 4, wherein
the second sidewall spacers include second internal sidewall spacers covering the top surfaces of the edge parts of the second gate electrode and side surfaces of the other part of the second gate electrode and second external sidewall spacers covering the side surfaces of the edge parts of the second gate electrode and the second internal sidewall spacers.

6. A semiconductor device comprising a first MIS transistor having a first gate electrode which is fully silicided with metal, the first MIS transistor including:
a first gate insulating film formed on a semiconductor substrate;
the first gate electrode formed on the first gate insulating film; and
first sidewall spacers formed on the side surfaces of the first gate electrode, wherein
the first gate electrode has a first part and a second part which is formed on the first part and has a width in the gate length direction smaller than that of the first part.

7. The semiconductor device of claim 6, wherein
the second part of the first gate electrode is sandwiched between the first sidewall spacers.

8. The semiconductor device of claim 6, wherein
the first gate electrode is convex-shaped when viewed in section.

9. The semiconductor device of claim 6, wherein
the first sidewall spacers include first internal sidewall spacers covering the side surfaces of the second part of the first gate electrode and first external sidewall spacers covering the side surfaces of the first part of the first gate electrode and side surfaces of the second part of the first gate electrode with the first internal sidewall spacers interposed therebetween.

10. The semiconductor device of claim 6 further comprising a second MIS transistor having a second gate electrode which is fully silicided with metal and has a gate length larger than that of the first gate electrode, the second MIS transistor including:
a second gate insulating film formed on the semiconductor substrate;
the second gate electrode formed on the second insulating film; and
second sidewall spacers formed on the side surfaces of the second gate electrode, wherein
the second gate electrode has a third part and a fourth part which is formed on the third part and has a width in the gate length direction smaller than that of the third part.

11. The semiconductor device of claim 10, wherein
the second sidewall spacers include second internal sidewall spacers covering side surfaces of the fourth part of the second gate electrode and second external sidewall spacers covering side surfaces of the third part of the second gate electrode and the side surfaces of the fourth part of the second gate electrode with the second internal sidewall spacers interposed therebetween.

12. A method for manufacturing a semiconductor device including a first MIS transistor having a first gate electrode which is fully silicided with metal, the method comprising the steps of:
(a) forming first sidewall spacers covering side and top surfaces of edge parts of a first silicon film pattern to be the first gate electrode;
(b) forming a metallic film on the first silicon film pattern after the step (a); and
(c) reacting the first silicon film pattern with the metallic film to cause full silicidation of the first silicon film pattern to form the first gate electrode after the step (b).

13. The method of claim 12, wherein
the semiconductor device further comprises a second MIS transistor having a second gate electrode which is fully silicided with metal and has a gate length larger than that of the first gate electrode,
the step (a) includes the step of forming second sidewall spacers covering side and top surfaces of edge parts of a second silicon film pattern to be the second gate electrode,
the step (b) includes the step of forming the metallic film on the second silicon film pattern and
the step (c) includes the step of reacting the second silicon film pattern with the metallic film to cause full silicidation of the second silicon film pattern to form the second gate electrode.

14. The method of claim 12, wherein
the step (a) includes the step of forming a silicon film and a protective film sequentially on a substrate, shaping the protective film and the silicon film into the form of the first gate electrode to obtain a first protective film pattern and the first silicon film pattern, reducing the width of the first protective film pattern from both edges thereof to expose top surfaces of the edge parts of the first silicon film pattern and forming the first sidewall spacers to cover the side and top surfaces of the edge parts and
the step of removing the first protective film pattern is performed between the steps (a) and (b).

15. The method of claim 12, wherein
the first sidewall spacers include internal sidewall spacers covering the top surfaces of the edge parts of the first silicon film pattern and external sidewall spacers covering the side surfaces of the edge parts of the first silicon film pattern and the internal sidewall spacers,
the step (a) includes the step of forming a silicon film and a protective film sequentially on a substrate, shaping the protective film into a first protective film pattern having a width smaller than the width of the first gate electrode by a predetermined amount reduced from both sides of the first gate electrode, forming the internal sidewall spacers to cover top surfaces of parts of the silicon film to be edge parts of the first gate electrode and the side surfaces of the first protective film pattern, shaping the silicon film into the form of the first gate electrode using the first protective film pattern and the internal sidewall spacers as a mask to obtain a first silicon film pattern and forming the external sidewall spacers to cover side surfaces of edge parts of the first silicon film pattern and the internal sidewall spacers, and
the step of removing the first protective film pattern is performed between the steps (a) and (b).

16. The method of claim 12, wherein
the step (a) includes the step of forming a silicon film and a protective film sequentially on a substrate, shaping the protective film into a first protective film pattern having a width smaller than the width of the first gate electrode by a predetermined amount reduced from both sides of the first gate electrode, forming dummy sidewall spacers to cover top surfaces of parts of the silicon film to be edge parts of the first gate electrode and the side surfaces of the first protective film pattern, shaping the silicon film into the form of the first gate electrode using the first protective film pattern and the dummy sidewall spacers as a mask to obtain a first silicon film pattern, removing the dummy sidewall spacers to expose the top surfaces of edge parts of the first silicon film pattern and forming the first sidewall spacers to cover the side and top surfaces of the edge parts, and
the step of removing the first protective film pattern is performed between the steps (a) and (b).
